(19) United States
(12) Patent Application Publication
(10) Pub. No.: US 2025/0203968 A1
(43) Pub. Date: Jun. 19, 2025

(54) SEMICONDUCTOR DEVICE WITH TWO-DIMENSIONAL MATERIALS AND FORMING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Yu-Tung Lin, Taoyuan City (TW); Yu-Wei Hsu, Taoyuan City (TW); Zih-Yun Fong, Pingtung City (TW); Yi-Feng Huang, Changhua County (TW); Chih-I Wu, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/402,905

(22) Filed: Jan. 3, 2024

Related U.S. Application Data
(60) Provisional application No. 63/610,421, filed on Dec. 15, 2023.

(51) Int. Cl. H01L 29/06; H01L 21/768; H01L 27/092; H01L 29/417

(52) U.S. Cl. CPC H10D 62/121; H01L 21/76834; H10D 64/251; H10D 84/856

(57) ABSTRACT

A device includes a first 2D semiconductor layer over a substrate, a first source/drain contact interfacing a first region of the first 2D semiconductor layer, and a second source/drain contact interfacing a second region of the first 2D semiconductor layer spaced apart from the first region of the first 2D semiconductor layer. The first source/drain contact includes an antimony layer interfacing the first region of the first 2D semiconductor layer, and a platinum layer over the antimony layer.

### PRIORITY CLAIM AND CROSS-REFERENCE

This application claims priority to U.S. Provisional Application Ser. No. 63/610,421, filed Dec. 15, 2023, which is herein incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a 2D semiconductor device in accordance with some embodiments of the present disclosure.

FIG. 1B illustrates a schematic view of a mono-layer of an example TMD in accordance with some example embodiments.

FIG. 2 is a graph illustrating Raman spectrum analysis results in different conditions, in accordance with some embodiments of the present disclosure.

FIG. 3A illustrates an exemplary band diagram of a semimetal-semiconductor junction between WSe₂ and pristine Sb, in accordance with some embodiments of the present disclosure.

FIG. 3B illustrates an exemplary band diagram of a semimetal-semiconductor junction between WSe₂ and pristine Pt, in accordance with some embodiments of the present disclosure.

FIG. 4A is a graph illustrating the current-voltage (I-V) characteristics of WSe₂-channel FETs, in accordance with some embodiments of the present disclosure.

FIG. 4B is a graph illustrating the on-current behaviors as a function of the Sb-to-Pt thickness ratio for WSe₂-channel FETs, in accordance with some embodiments of the present disclosure.

FIG. 5 illustrates a cross-sectional view of a 2D semiconductor device in accordance with some embodiments of the present disclosure.

FIG. 6 is a graph showing NFET drain current improvement attributable to an n-type drain-current improvement layer, in accordance with some embodiments of the present disclosure.

FIG. 7 illustrates a cross-sectional view of a 2D semiconductor device in accordance with some embodiments of the present disclosure.

FIG. 8 is a graph showing PFET drain current improvement attributable to a p-type drain-current improvement layer, in accordance with some embodiments of the present disclosure.

FIGS. 9-28A illustrate cross-sectional views of intermediate stages in the formation of semiconductor devices in accordance with some embodiments of the present disclosure.

FIG. 28B is an example top view of the structure in FIG. 28A, in accordance with some embodiments of the present disclosure.

FIGS. 29-33 illustrate cross-sectional views of intermediate stages in the formation of semiconductor devices in accordance with some embodiments of the present disclosure.

FIG. 34 illustrates an exemplary cross sectional view of semiconductor devices according to some other embodiments of the present disclosure.

FIG. 35 illustrates an exemplary cross sectional view of semiconductor devices according to some other embodiments of the present disclosure.

FIG. 36 illustrates an exemplary cross sectional view of semiconductor devices according to some other embodiments of the present disclosure.

FIG. 37 illustrates an exemplary cross sectional view of semiconductor devices according to some other embodiments of the present disclosure.

FIG. 38 illustrates an exemplary cross sectional view of semiconductor devices according to some other embodiments of the present disclosure.

FIG. 39 illustrates an exemplary cross sectional view of semiconductor devices according to some other embodiments of the present disclosure.

FIG. 40 illustrates an exemplary cross sectional view of semiconductor devices according to some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be varied with the down-scaling of the integrated circuits.

With the progress of transistor process technology, the dimension of transistors has shrunk and therefore the number of transistors per unit area of an integrated circuit has increased accordingly. However, the off-state current has dramatically increased with further reduction in the channel length of a transistor, i.e., short channel effect. This effect is the major challenge of further increasing the density of transistors. Reducing the thickness of channel is known as one way of suppressing short channel effect. Two-dimensional (2D) semiconductors can serve as ultra-thin semiconductor channel material candidate to suppress the short channel effect. One advantageous feature of the 2D semiconductor material is the high electron mobility value, which is within a range of about 50-1000 cm²/V-see or even higher. It is understood that silicon, when formed to a low thickness (e.g., about 3 nm or lower) comparable with a thickness of a 2D semiconductor film, can have its mobility degraded drastically. Therefore, 2D semiconductor channel thickness can be scaled down with less impact on carrier mobility than silicon, which in turn achieves satisfactory channel mobility with only few nanometers in channel thickness (e.g., less than 3 nm). For example, tungsten diselenide (WSe₂) can be utilized as a two-dimensional (2D) semiconductor channel material, with palladium (Pd) contacts disposed on the WSe₂ layer to function as source/drain electrodes. However, it has been observed that the junction formed between Pd and WSe₂ is susceptible to significant Fermi level pinning (FLP) effects, a phenomenon where the Fermi level becomes “pinned” at a particular energy level at the junction. This issue adversely impacts the device's performance. Furthermore, the junction formed between Pd and WSe₂ exhibits unsatisfactory band alignment for hole conduction, resulting in an elevated Schottky barrier, increased contact resistance, and diminished current delivery capabilities. Consequently, this structure is not suitable for implementation in p-type transistors.

The present disclosure provides, in various embodiments, improved source/drain contacts including an antimony (Sb) layer interfacing WSe₂ layer and a platinum (Pt) layer over the Sb layer. The Sb—Pt contacts mitigate the Fermi level pinning issues commonly encountered in 2D semiconductor devices when Pd contacts are used. Moreover, the effective work function of the Sb—Pt contacts is tunable by varying the thickness ratio between the Sb and Pt layers. This unique feature advantageously improves the performance of both p-type and n-type field effect transistors (p-FETs and n-FETs).

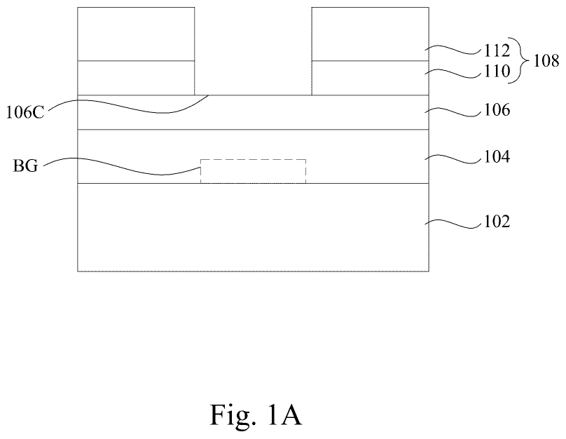

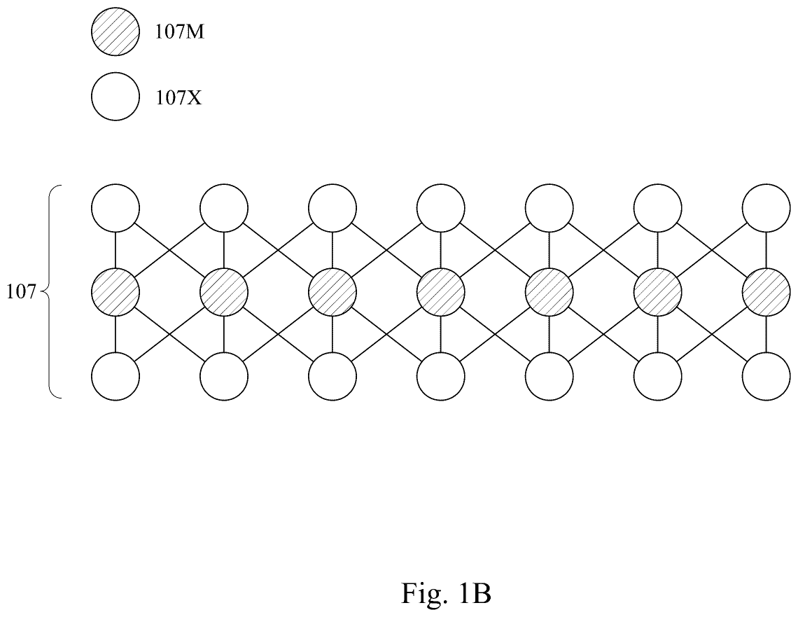

FIG. 1A illustrates a cross-sectional view of a 2D semiconductor device in accordance with some embodiments of the present disclosure. The 2D semiconductor device includes a substrate 102. In some embodiments, the substrate 102 may be a semiconductor substrate, such as a bulk semiconductor, a semiconductor-on-insulator (SOI) substrate, or the like, which may be doped (e.g., with a p-type or an n-type impurity) or undoped. The substrate 102 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The 2D semiconductor device further includes a dielectric layer 104 formed over the substrate 102 In some embodiments, the dielectric may be formed of a dielectric material, which may be deposited by any suitable method, such as CVD, plasma-enhanced CVD (PECVD), FCVD, or the like. Acceptable dielectric materials may include silicon nitride (SiNₓ), phospho-silicate glass (PSG), boro-silicate glass (BSG), boron-doped phospho-silicate glass (BPSG), undoped silicate glass (USG), high-k dielectrics, or the like. Other insulation materials formed by any acceptable process may be used. In certain embodiments, the dielectric layer 104 is a nitride-based material, such as silicon nitride (SiNₓ).

The 2D semiconductor device further includes a 2D semiconductor layer 106 formed over the dielectric layer 104. The 2D semiconductor materials of the 2D semiconductor layer 106 are usually few-layer thick and exist as stacks of strongly bonded layers with weak interlayer van der Waals attraction, allowing the layers to be mechanically or chemically exfoliated into individual, atomically thin layers. The 2D semiconductor materials are promising candidates of the channel, source, drain materials of transistors. Examples of 2D semiconductor materials include transition metal dichalcogenides (TMDs), graphene, layered III-VI chalcogenide, graphene, hexagonal Boron Nitride (h-BN), black phosphorus or the like. The 2D semiconductor may include one or more layers and can have a thickness within the range of about 0.5-100 nm in some embodiments. One advantageous feature of the few-layered 2D semiconductor is the high electron mobility value, which is within a range of about 50-1000 cm²/V-see or even higher. It is understood that the bulk silicon, when cut to a low thickness (e.g., about 3 nm) comparable with a thickness of a 2D material film, may have its mobility degraded drastically.

In some embodiments, the 2D semiconductor layers 106 is a transition metal dichalcogenide (TMD) material which has the formula MX₂, wherein M is a transition metal element such as titanium, vanadium, cobalt, nickel, zirconium, molybdenum, technetium, rhodium, palladium, hafnium, tantalum, tungsten, rhenium, iridium, platinum, and X is a chalcogen such as sulfur, selenium, or tellurium. Examples of dichalcogenide materials that are suitable for the 2D semiconductor layer 106 include WSe₂, WS₂, MoS₂, MoSe₂, MoTe₂, WTe₂, the like, or a combination thereof. However, any suitable transition metal dichalcogenide material may alternatively be used. Once formed, the transition metal dichalcogenide material is in a layered structure with a plurality of two-dimensional layers of the general form X-M-X, with the chalcogen atoms in two planes separated by a plane of metal atoms.

The 2D semiconductor layer 106 may be a mono-layer or may include a few mono-layers. FIG. 1B illustrates a schematic view of a mono-layer 107 of an example TMD in accordance with some example embodiments. In FIG. 1B, the one-molecule thick TMD material layer comprises transition metal atoms 107M and chalcogen atoms 107X. The transition metal atoms 107M may form a layer in a middle region of the one-molecule thick TMD material layer, and the chalcogen atoms 107X may form a first layer over the layer of transition metal atoms 107M, and a second layer underlying the layer of transition metal atoms 107M. The transition metal atoms 107M may be W atoms or Mo atoms, while the chalcogen atoms 107X may be Se atoms, S atoms, or Te atoms. In the example of FIG. 1B, each of the transition metal atoms 107M is bonded (e.g. by covalent bonds) to six chalcogen atoms 107X, and each of the chalcogen atoms 107X is bonded (e.g. by covalent bonds) to three transition metal atoms 107M. Throughout the description, the illustrated cross-bonded layers including one layer of transition metal atoms 107M and two layers of chalcogen atoms 107X in combination are referred to as a mono-layer 107 of TMD.

In some embodiments, the 2D semiconductor layer 106 is formed by using, for example, depositing a transition metal layer (e.g., tungsten (W) layer) over the dielectric layer 104, followed by selenizing the transition metal layer into a transition metal dichalcogenide (TMD) layer 106. In some other embodiments, the 2D semiconductor layer 106 is formed by an inductively-coupled-plasma (ICP) CVD process using a transition metal-containing precursor (e.g., WF₆) and a selenium-containing precursor (e.g., H₂Se). In some embodiments, the 2D semiconductor layer 103 may be deposited to have a thickness in a range from about 1 nm to about 10 nm, depending on a total count of mono-layers. The process conditions are controlled to achieve the desirable total count of mono-layers 107 in a 2D semiconductor layer 106.

In some other embodiments, the 2D semiconductor layer 106 is formed using exfoliation and taping method. For example, a 2D semiconductor layer can be grown on another crystalline substrate with a desired crystal orientation by using suitable deposition techniques, and the 2D semiconductor layer 106 is then transferred onto the dielectric layer 104. For example, the 2D semiconductor layer grown on the crystalline substrate can be covered with a protection film (e.g., PMMA) and a thermal release tape, and then the 2D semiconductor layer is mechanically or chemically exfoliated from the crystalline substrate and then transferred onto the dielectric layer 104. Next, the thermal release tape can be removed by, for example, baking the thermal release tape, so that the thermal release tape loses adhesiveness. Next, the protection film can be removed by, for example, etching or dissolving. After removal of the protection film, a 2D semiconductor layer 106 remains on the dielectric layer 104, and is ready for following processing of Sb—Pt contacts formation.

The 2D semiconductor device further includes multilayer source/drain contacts 108 formed over source/drain regions of the 2D semiconductor layer 106. The source/drain contacts 108 and the 2D semiconductor layer 106 can collectively serve as a field effect transistor (FET) using a 2D channel region 106C as a transistor channel. In some embodiments, the 2D channel region 106C extends laterally between the source/drain contacts 108 and is controlled by a transistor gate, such as back gate BG disposed under the dielectric layer 104. In some embodiments where the 2D semiconductor layer 106 is WSe₂, the resultant transistor can be referred to as a WSe₂-channel FET. In some embodiments, each multilayer contact 108 includes a first semimetal layer 110 interfacing the source/drain region of the 2D semiconductor layer 106, and a second semimetal layer 112 over the first semimetal layer 110. In some embodiments, the material chosen for the first semimetal layer 110 is antimony (Sb), while the material for the overlying second semimetal layer 112 is platinum (Pt). In semimetals, the valence band and the conduction band overlap slightly or touch at a point, leading to a zero or near-zero band gap. There are both electrons and holes at the Fermi level of semimetals, and the dominant charge carriers depend on the energy band structure at the semimetal-semiconductor junction between the semimetal and the 2D semiconductor layer 106.

The Sb layer 110 performs dual functions: firstly, it serves as an intermediary or buffer layer between the high work function Pt layer 112 and the 2D semiconductor layer 106, effectively reducing potential damages to the 2D semiconductor layer 106; secondly, it attenuates the interaction between the 2D semiconductor and the adjoining metal, thereby alleviating issues related to Fermi level pinning (FLP), which are notoriously prevalent in 2D semiconductor interfaces employing palladium (Pd) contacts.

The deficiency of using Pd contacts in 2D semiconductor devices stems from an acute susceptibility to strong Fermi level pinning, induced primarily by defect-induced gap states (DIGS) and metal-induced gap states (MIGS). These phenomena collectively compromise the tunability of the effective work function at the metal-semiconductor interface. By introducing the Sb buffer layer 110, the present disclosure transcends this limitation. The Sb buffer layer 110 can be deposited under relatively milder conditions, specifically at a lower temperature compared to Pd deposition, which minimizes thermal stresses and lattice damage to the 2D semiconductor layer 106, thereby reducing defects at the interface between the Sb buffer layer 110 and the 2D semiconductor layer 106, which in turn reduces at least the defect-induced gap states (DIGS). The relatively lower sublimation point of Sb compared to Pd ensures that evaporative deposition techniques induce minimal thermal disruption, thus preserving the integrity of the 2D semiconductor layer 106.

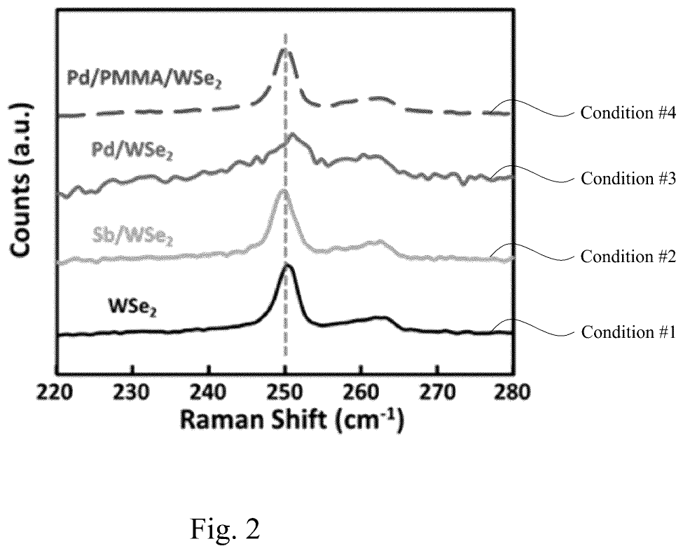

FIG. 2 is a graph illustrating Raman spectrum analysis results in different conditions. These Raman spectra are obtained by carrying out Raman spectroscopy on structures with varying compositions. In Condition #1, the Raman spectroscopy is performed on a structure comprising a WSe₂ layer formed on a SiNₓ layer. In Condition #2, the Raman spectroscopy is performed on a structure comprising a dual-layer stack formed on SiNₓ layer, wherein the dual-layer stack comprises a WSe₂ layer and a Sb layer formed on the WSe₂ layer. In Condition #3, the Raman spectroscopy is performed on a structure comprising a dual layer stack formed on SiNₓ layer, wherein the dual-layer stack comprises a WSe₂ layer and a Pd layer formed on the WSe₂ layer. In Condition #4, the Raman spectroscopy is performed on a structure comprising a tri-layer stack formed on SiNₓ layer, wherein the tri-layer stack comprises a WSe₂ layer, a polystyrene and polymethyl methacrylate (PMMA) layer formed the WSe₂ layer, and a Pd layer formed on the PMMA layer.

Comparative analysis of the Raman shift curves as shown in FIG. 2 reveals following insights. Comparing Condition #2 with Condition #1, it can be observed that the dual-layer stack of Sb/WSe₂ has the same or similar Raman shift curve as the pristine WSe₂. Comparing Condition #3 with Condition #1, it can be observed that the dual-layer stack of Pd/WSe₂ has a distinctly different Raman shift curve from the pristine WSe₂. Comparing Condition #4 with Condition #1, it can be observed that the tri-layer stack of Pd/PMMA/WSe₂ has the same or similar Raman shift curve as the pristine WSe₂. Based on these observations, it can be concluded that formation of Sb directly on WSe₂ results in reduced lattice damage to WSe₂ when compared to the lattice damage incurred by the formation of Pd directly on WSe₂.

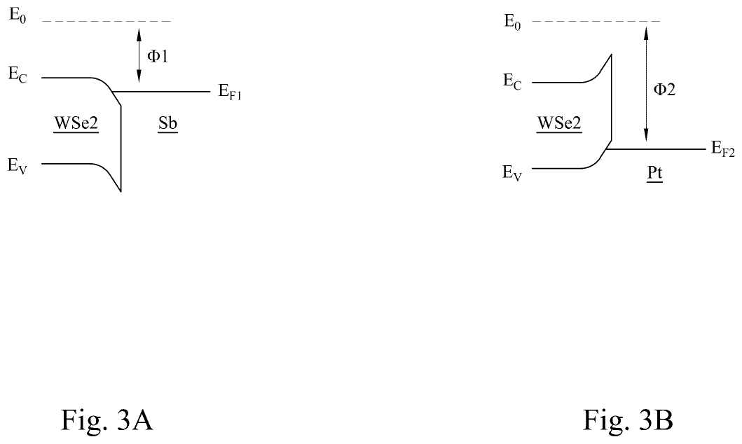

FIG. 3A illustrates an exemplary band diagram of a semimetal-semiconductor junction between WSe₂ and pristine Sb, in accordance with some embodiments of the present disclosure. In FIG. 3A, Ec denotes a conduction band edge of WSe₂, Ev denotes a valence band edge of WSe₂, and E_{F1} denotes the Fermi level within Sb. A work function (Φ₁) may be a minimum thermodynamic work (energy) needed to remove an electron from a solid to a point in a vacuum outside the solid surface. The vacuum level (E₀) represents the minimum energy that an electron needs to possess in order to completely free itself from a semimetal or semiconductor. As illustrated in FIG. 3A, due to the semimetal property of Sb, the Fermi level E_{F1} lies at the point where the valence and conduction bands of Sb either touch or exhibit a slight overlap, also referred to as the Dirac points. In certain embodiments, Sb has a work function Φ₁ of about 4.4 eV±0.3 eV, such as about 4.4 eV. Therefore, the work function Φ₁ allows for the Fermi level E_{F1} getting closer to the conduction band Ec than to the valance band Ev, which favors electrons to act as dominant carriers flowing through channel regions of WSe₂, allowing the WSe₂-channel FET to operate as an n-type field effect transistor (NFET).

FIG. 3B illustrates an exemplary band diagram of a semimetal-semiconductor junction between WSe₂ and pristine Pt, in accordance with some embodiments of the present disclosure. In FIG. 3B, Ec denotes a conduction band edge of WSe₂, Ev denotes a valence band edge of WSe₂, and E_{F2} denotes the Fermi level within Pt. A work function (Φ₂) may be a minimum thermodynamic work (energy) needed to remove an electron from a solid to a point in a vacuum outside the solid surface. The vacuum level (E₀) represents the minimum energy that an electron needs to possess in order to completely free itself from a semimetal or semiconductor. As illustrated in FIG. 3B, due to the semimetal property of Pt, the Fermi level E_{F2} lies at the point where the valence and conduction bands of Pt may slightly overlap. In certain embodiments, Pt has a work function Φ₂ of about 5.6 eV±0.3 eV, such as about 5.6 eV. Therefore, the work function Φ₂ allows that the Fermi level E_{F2} lies closer to the valance band Ev than to the conduction band Ec, which leads to hole-dominant transport, allowing the WSe₂-channel FET to operate as a p-type field effect transistor (PFET).

In some embodiments, the multilayer source/drain contacts 108 each comprise stacked layers of Sb and Pt. These materials exhibit work function of approximately 4.4 eV and 5.6 eV, respectively, allowing for an effective work function ranging from about 4.4 eV to 5.6 eV. By tuning a thickness ratio of Sb to Pt, it is feasible to tune the effective work function of the multilayer source/drain contacts 108, thereby modulating the carrier polarity of the WSe₂-channel FET. For example, if the thickness ratio of Sb to Pt exceeds 100%, the resulting WSe₂-channel FET primarily functions as an NFET; if the thickness ratio of Sb to Pt is less than 100%, then the resulting WSe₂-channel FET can operate predominantly as a PFET.

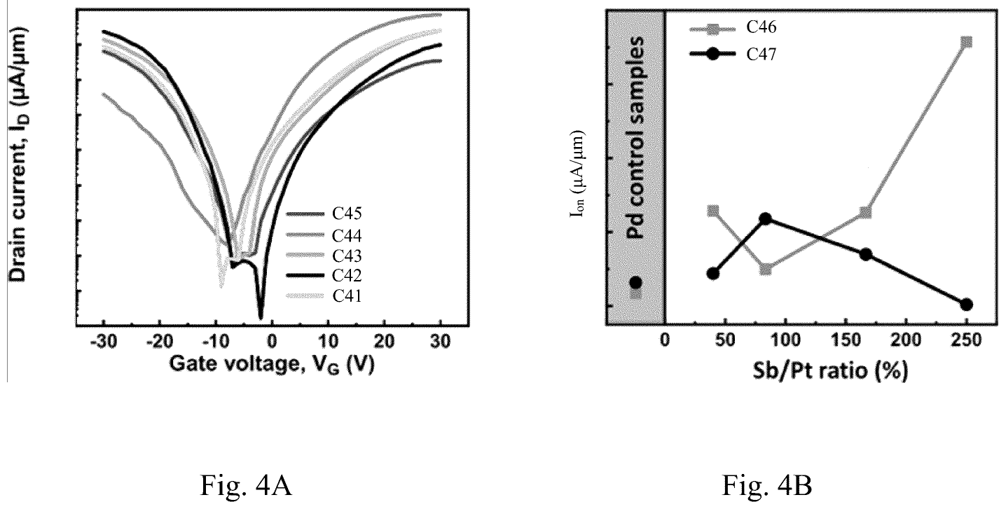

FIGS. 4A and 4B are graphs illustrating experimental results of device performance of various WSe₂-channel FETs having different thickness ratios of Sb to Pt, elucidating the relationship between the drain current/on-current improvement and the Sb-to-Pt thickness ratio. FIG. 4A plots the current-voltage (I-V) characteristics of WSe₂-channel FETs, in accordance with some embodiments of the present disclosure. In FIG. 4A, the drain current (Id) is shown on the vertical axis, and the gate voltage (VG) is shown on the horizontal axis. The I-V curve C41 represents a current-voltage characteristic of a WSe₂-channel FET including source/drain contacts with a Sb-to-Pt thickness ratio of about 10:25 (e.g., source/drain contacts having 10 nm-thick Sb and 25 nm-thick Pt). The I-V curve C42 represents a current-voltage characteristic of a WSe₂-channel FET including source/drain contacts with Sb-to-Pt thickness ratio of about 10:12 (e.g., source/drain contacts having 10 nm-thick Sb and 12 nm-thick Pt). The I-V curve C43 represents a current-voltage characteristic of a WSe₂-channel FET including source/drain contacts with Sb-to-Pt thickness ratio of about 20:12 (e.g., source/drain contacts having 20 nm-thick Sb and 12 nm-thick Pt). The I-V curve C44 represents a current-voltage characteristic of a WSe₂-channel FET including source/drain contacts with Sb-to-Pt thickness ratio of about 30:12 (e.g., source/drain contacts having 30 nm-thick Sb and 12 nm-thick Pt). The I-V curve C45 represents a current-voltage characteristic of a WSe₂-channel FET including source/drain contacts formed from 30 nm-thick Pd.

As evidenced in FIG. 4A, the I-V curve C44 demonstrates a drain current behavior superior than other I-V curves under positive gate voltage conditions, whereas the I-V curve C42 demonstrates a drain current behavior superior than other I-V curves under negative gate voltage conditions. These observations suggest that when source/drain contacts has a Sb—Pt thickness ratio of about 30:12 (e.g., source/drain contacts having 30 nm-thick Sb and 12 nm-thick Pt), the resulting WSe₂-channel FET has optimal NFET performance; and when source/drain contacts has Sb—Pt thickness ratio of about 10:12 (e.g., source/drain contacts having 10 nm-thick Sb and 12 nm-thick Pt), the resulting WSe₂-channel FET has optimal PFET performance.

FIG. 4B plots the on-current behaviors as a function of the Sb-to-Pt thickness ratio for WSe₂-channel FETs, in accordance with some embodiments of the present disclosure. The plot line C46 represents NFET on-current levels when the WSe₂-channel FETs with different Sb-to-Pt thickness ratios operate in NFET mode (i.e., under a positive gate voltage), and the plot line C47 represents PFET on-current levels when the WSe₂-channel FETs with different Sb-to-Pt thickness ratios operate in PFET mode (i.e., under a negative gate voltage). As illustrated in FIG. 4B, when the Sb-to-Pt thickness ratio exceeds 200% (e.g., about 30:12), a maximal NFET on-current can be achieved; when the Sb-to-Pt thickness ratio is in a range from about 75% to about 100% (e.g., about 10:12), a maximal PFET on-current can be achieved.

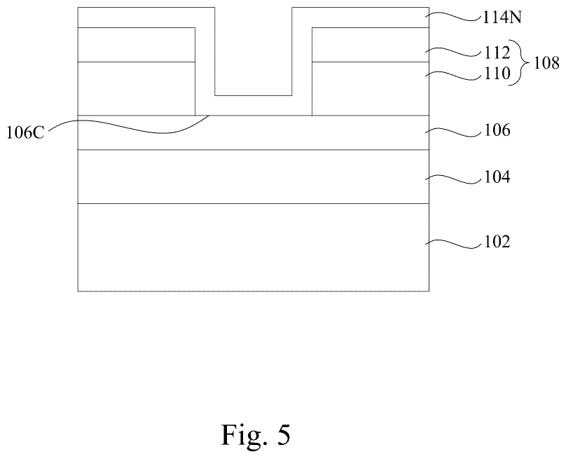

FIG. 5 illustrates a cross-sectional view of a 2D semiconductor device in accordance with some embodiments of the present disclosure. The structure as illustrated in FIG. 5 is similar to that of FIG. 1A, except that the structure in FIG. 5 further includes an n-type drain-current improvement layer 114N (also referred to as capping layer in this context) capping the source/drain contacts 108 and also the 2D channel region 106C. The n-type drain-current improvement layer 114N has a material suitable for increasing drain current when the WSe₂-channel FET is operate under NFET mode (i.e., under positive gate voltage conditions). In some embodiments, the n-type drain-current improvement layer 114N is a silicon oxynitride (SiONₓ) layer, a hafnium oxide (HfOₓ) layer, an aluminum oxide (AlOₓ) layer, a titanium oxide (TiOₓ) layer, combinations thereof, or the like, which is deposited over the source/drain contacts 108 and the 2D channel region 106C by using suitable deposition technique such as CVD, plasma-enhanced CVD (PECVD), atomic layer deposition (ALD), or the like. In some embodiments, the n-type drain-current improvement layer 114N has a thickness in a range from about 1 nm to 50 nm.

As illustrated in FIG. 5, the source/drain contacts 108 serving for NFETs has the first semimetal layer 110 thicker than the second semimetal layer 112. The n-type drain-current improvement layer 114N thus forms an interface with a sidewall of the first semimetal layer 110 larger than an interface with a sidewall of the second semimetal layer 112. For example, an area ratio of a sidewall interface between the first semimetal layer 110 and the n-type drain-current improvement layer 114N to a sidewall interface between the second semimetal layer 112 and the n-type drain-current improvement layer 114N is about 30:12.

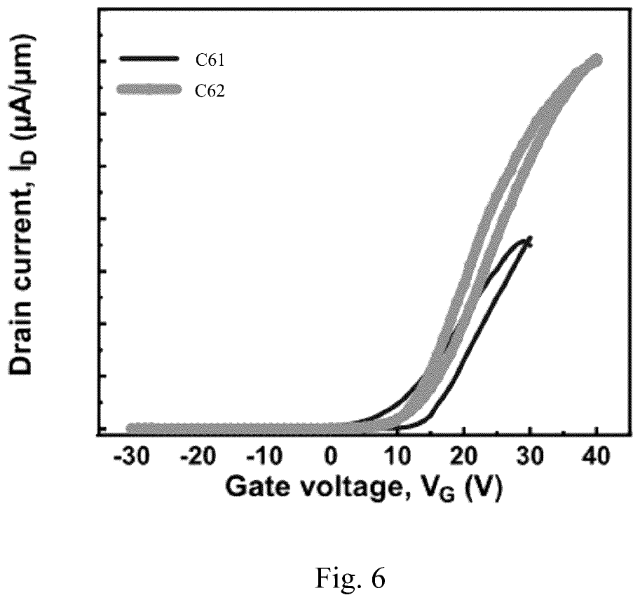

FIG. 6 is a graph showing NFET drain current improvement attributable to the n-type drain-current improvement layer 114N, in accordance with some embodiments of the present disclosure. In particular, FIG. 6 illustrates experimental results of current-voltage (I-V) characteristics of WSe₂-channel FETs, which are different in the presence with n-type drain-current improvement layer 114N. The curve C61 represents a current-voltage characteristic of a WSe₂-channel FET including source/drain contacts with a Sb-to-Pt thickness ratio of about 30:12 (e.g., source/drain contacts having 30 nm-thick Sb and 12 nm-thick Pt), but devoid of the n-type drain-current improvement layer 114N. The curve C62 represents a current-voltage characteristic of a WSe₂-channel FET including source/drain contacts with a Sb-to-Pt thickness ratio of about 30:12 (e.g., source/drain contacts having 30 nm-thick Sb and 12 nm-thick Pt) capped by an n-type drain-current improvement layer 114N (e.g., SiONₓ). As evidenced in FIG. 6, the I-V curve C62 demonstrates a drain current behavior superior than the I-V curve C61 under conditions of positive gate voltage. This data corroborates that the integration of the n-type drain-current improvement layer 114N, capping the source/drain contacts 108 and the 2D channel region 106C, serves to elevate the drain current when the WSe₂-channel FET is operated in NFET mode. Moreover, it is observed that the drain-current of n-type WSe₂-channel FET with the n-type drain-current improvement layer 114N capping the Sb—Pt contacts is greater than that of n-type WSe₂-channel FET with other metal contacts (e.g., Ag contacts, Au contacts, In contacts, Ni contacts, Ti contacts, or combinations thereof). In some embodiments, the WSe₂-channel FET with the n-type drain-current improvement layer 114N has an effective mobility (μeff) in a range from about 7.5 cm²/v-s to about 8.2 cm²/v-s (e.g., about 7.8 cm²/v-s), and a contact resistance (R_{c}) in a range from about 1.5 k Ω·μm to about 2.0 k Ω·μm (e.g., about 1.8 k Ω·μm).

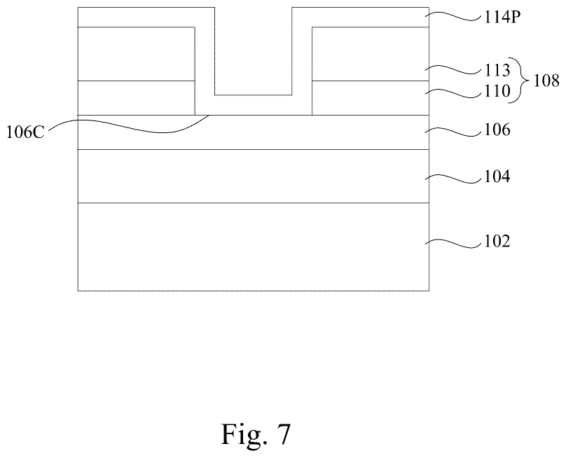

FIG. 7 illustrates a cross-sectional view of a 2D semiconductor device in accordance with some embodiments of the present disclosure. The structure as illustrated in FIG. 7 is similar to that of FIG. 1A, except that the structure in FIG. 7 further includes a p-type drain-current improvement layer 114P (also referred to as capping layer) capping the source/drain contacts 108 and also the 2D channel region 106C. The p-type drain-current improvement layer 114P has a material suitable for increasing drain current when the WSe₂-channel FET is operate under PFET mode (i.e., under negative gate voltage conditions). In some embodiments, the p-type drain-current improvement layer 114P is a molybdenum oxide (MoOₓ) layer, a nitrogen dioxide (NO₂) layer, an tungsten oxide (WOₓ) layer, a iodine (I₂) layer, combinations thereof, or the like, which is deposited over the source/drain contacts 108 and the 2D channel region 106C by using suitable deposition technique such as CVD, plasma-enhanced CVD (PECVD), atomic layer deposition (ALD), or the like. In some embodiments, the p-type drain-current improvement layer 114P has a thickness in a range from about 1 nm to 50 nm.

As illustrated in FIG. 7, the source/drain contacts 108 serving for PFETs has the first semimetal layer 110 thinner than the second semimetal layer 112. The p-type drain-current improvement layer 114P thus forms an interface with a sidewall of the first semimetal layer 110 smaller than an interface with a sidewall of the second semimetal layer 112. For example, an area ratio of a sidewall interface between the first semimetal layer 110 and the p-type drain-current improvement layer 114P to a sidewall interface between the second semimetal layer 112 and the p-type drain-current improvement layer 114P is about 10:12.

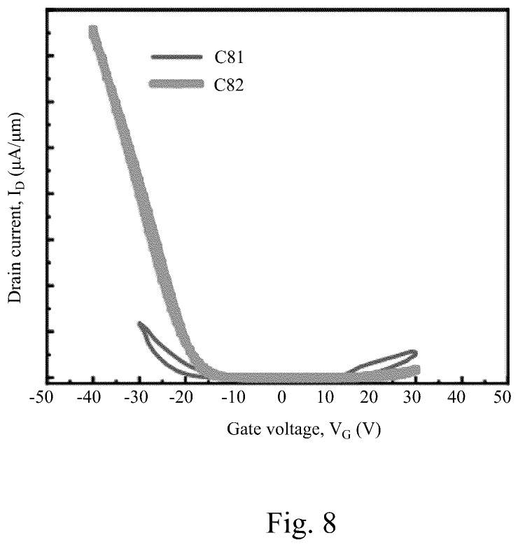

FIG. 8 is a graph showing PFET drain current improvement attributable to the p-type drain-current improvement layer 114P, in accordance with some embodiments of the present disclosure. In particular, FIG. 8 illustrates experimental results of current-voltage (I-V) characteristics of WSe₂-channel FETs, which are different in the presence with p-type drain-current improvement layer 114P. The curve C81 represents a current-voltage characteristic of a WSe₂-channel FET including source/drain contacts with a Sb-to-Pt thickness ratio of about 10:12 (e.g., source/drain contacts having 10 nm-thick Sb and 12 nm-thick Pt), but devoid of the p-type drain-current improvement layer 114P. The curve C82 represents a current-voltage characteristic of a WSe₂-channel FET including source/drain contacts with a Sb-to-Pt thickness ratio of about 10:12 (e.g., source/drain contacts having 10 nm-thick Sb and 12 nm-thick Pt) capped by a p-type drain-current improvement layer 114P (e.g., MoOₓ). As evidenced in FIG. 8, the I-V curve C82 demonstrates a drain current behavior superior than the I-V curve C81 under conditions of negative gate voltage. This data corroborates that the integration of the p-type drain-current improvement layer 114P, capping the source/drain contacts 108 and the 2D channel region 106C, serves to elevate the drain current when the WSe₂-channel FET is operated in PFET mode. Moreover, it is observed that the drain-current of p-type WSe₂-channel FET with the p-type drain-current improvement layer 114P capping the Sb—Pt contacts is greater than that of p-type WSe₂-channel FET with other metal contacts (e.g., Ru contacts, Au contacts, Pd contacts, In contact, Ni contacts, Ti contacts, or combinations thereof). In some embodiments, the WSe₂-channel FET with the p-type drain-current improvement layer 114P has an effective mobility (μeff) in a range from about 10.5 cm²/v-s to about 11.5 cm²/v-s (e.g., about 10.8 cm²/v-s), and a contact resistance (R_{c}) in a range from about 0.7 kΩ·μm to about 1.0 kΩ·μm (e.g., about 0.9 k Ω·μm).

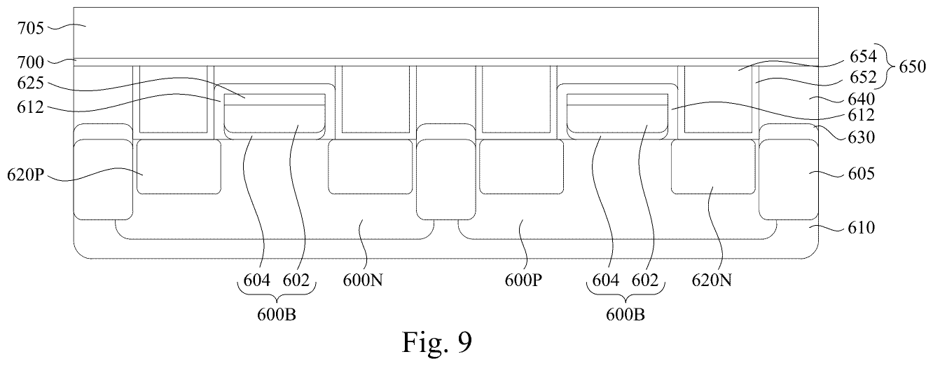

FIGS. 9 through 28A illustrate cross-sectional views of intermediate stages in the formation of semiconductor devices in accordance with some embodiments of the present disclosure. Throughout the various views and illustrative embodiments, like reference numbers are used to designate like elements. It is understood that additional operations can be provided before, during, and after the processes shown by FIGS. 9-28A, and some of the operations described below can be replaced or eliminated, for additional embodiments of the method. The order of the operations/processes may be interchangeable.

As illustrated in FIG. 9, an initial structure is received. The initial structure includes a substrate 610. The substrate 610 includes an N-well region 600N and a P-well region 600P, in which the N-well region 600N may be doped with N-type impurities (e.g., phosphorus, arsenic, antimony, or the like), and the P-well region 600P may be doped with P-type impurities (e.g., boron, boron fluoride, indium, or the like). The substrate 610 may be a semiconductor material and may include a graded layer or a buried oxide, for example. Other materials, such as germanium, quartz, sapphire, and glass could alternatively be used for the substrate 610. Alternatively, the silicon substrate 610 may be an active layer of a semiconductor-on-insulator (SOI) substrate or a multi-layered structure such as a silicon-germanium layer formed on a bulk silicon layer.

Isolation structures 605 are disposed in the substrate 610. In some embodiments, the isolation structures 605 may include oxide, such as silicon dioxide. The isolation structures 605, which act as a shallow trench isolation (STI) around the P-well region 600P from the N-well region 600N, may be formed by chemical vapor deposition (CVD) techniques using tetra-ethyl-ortho-silicate (TEOS) and oxygen as a precursor.

A gate structure 600A is disposed over the P-well region 600P of the substrate 610, and a gate structure 600B is disposed over the N-well region 600N of the substrate 610. In some embodiments, each of the gate structure 600A and the gate structure 600B includes a gate dielectric 602 and a gate electrode 604. In some embodiments, the gate dielectric 602 may be, for example, silicon oxide, silicon nitride, a combination thereof, or the like, and may be deposited or thermally grown according to acceptable techniques. In some embodiments, the gate electrode 604 may include polycrystalline-silicon (poly-Si) or poly-crystalline silicon-germanium (poly-SiGe). In some other embodiments, the gate structure 600A and the gate structure 600B may be metal gate structures, which include a high-k dielectric layer, a work function metal layer over the high-k dielectric layer, and a gate metal over the work function metal layer.

Capping layers 625 are disposed over the gate structures 600A and 600B. In some embodiments, the capping layers 625 may be oxide. A plurality of gate spacers 612 are disposed on opposite sides of the gate structure 600A and the gate structure 600B. In some embodiments, the gate spacers 612 may include SiO₂, Si₃N₄, SiOₓN_{y}, SiC, SiCN films, SiOC, SiOCN films, and/or combinations thereof.

N-type source/drain regions 620N are disposed in the P-well region 600P of the substrate 610 and on opposite sides of the gate structure 600A, and p-type source/drain regions 620P are disposed in the N-well region 620N of the substrate 610 and on opposite sides of the gate structure 600B. In some embodiments, the n-type source/drain regions 620N may be doped with N-type impurities, and the p-type source/drain regions 620P may be doped with p-type impurities. In some embodiments, the source/drain regions 620N, 620P may be may be formed by performing an epitaxial growth process that provides an epitaxy material over the substrate 610, and thus the source/drain regions 620N, 620P can be interchangeably referred to as epitaxy structures 620N, 620P in this context. In various embodiments, the source/drain regions 620N, 620P may include Ge, Si, GaAs, AlGaAs, SiGe, GaAsP, SiP, or other suitable materials.

A contact etch stop layer (CESL) 630 is disposed over the isolation structures 605 and over the capping layers 625. An interlayer dielectric (ILD) layer 640 is disposed over the CESL 630 and surrounds the gate structures 600A and 600B. In some embodiments, the CESL 630 includes silicon nitride, silicon oxynitride or other suitable materials. The CESL 630 can be formed using, for example, plasma enhanced CVD, low pressure CVD, ALD or other suitable techniques. In some embodiments, the ILD layer 640 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 640 may be formed using, for example, CVD, ALD, spin-on-glass (SOG) or other suitable techniques.

Source/drain contacts 650 are disposed in the ILD layer 640 and in contact with the source/drain regions 620N and 620P. In some embodiments, each source/drain contact 650 includes a barrier layer 652 and a contact plug 654. The barrier layer 652 is between the contact plug 654 and the underlying source/drain regions 620N or 620P. In some embodiments, the barrier layer 652 assists with the deposition of the contact plug 654 and helps to reduce out-diffusion of a metal material of the contact plug 654. In some embodiments, the barrier layer 652 includes titanium (Ti), titanium nitride (TiN), tantalum (Ta), tantalum nitride (TaN), or another suitable material. The contact plug 654 includes a conductive material, such tungsten (W), copper (Cu), aluminum (Al), ruthenium (Ru), cobalt (Co), molybdenum (Mo), nickel (Ni), or other suitable conductive materials. In some embodiments, the source/drain contacts 650 are formed of different materials than the foregoing multilayer source/drain contacts 108, because the source/drain contacts 650 are not in contact with a 2D semiconductor material (e.g., WSe₂).

An etch stop layer (ESL) 700 is disposed over the ILD layer 640 and the source/drain contacts 650. An inter-metal dielectric (IMD) layer 705 is disposed over the ESL 700. The material and the formation method of the ESL 700 are similar to those of the CESL 630. Moreover, the material and the formation method of the IMD layer 705 are similar to those of the ILD layer 640.

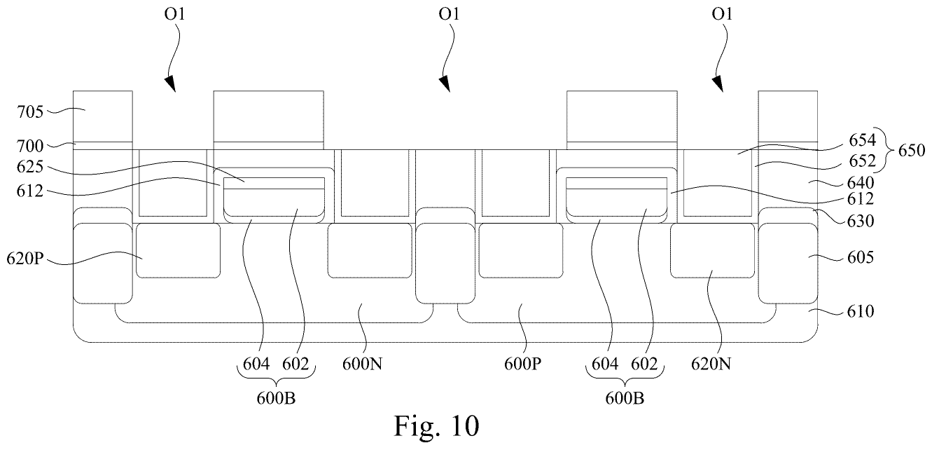

In FIG. 10, the ESL 700 and the IMD layer 705 are patterned to form trenches O1 to expose the source/drain contacts 650, by using suitable photolithography and etching techniques. In some embodiments, a trench O1 exposes a source/drain contact 650, and another trench O1 laterally extends a longer length to expose source/drain contacts 650 of neighboring transistors.

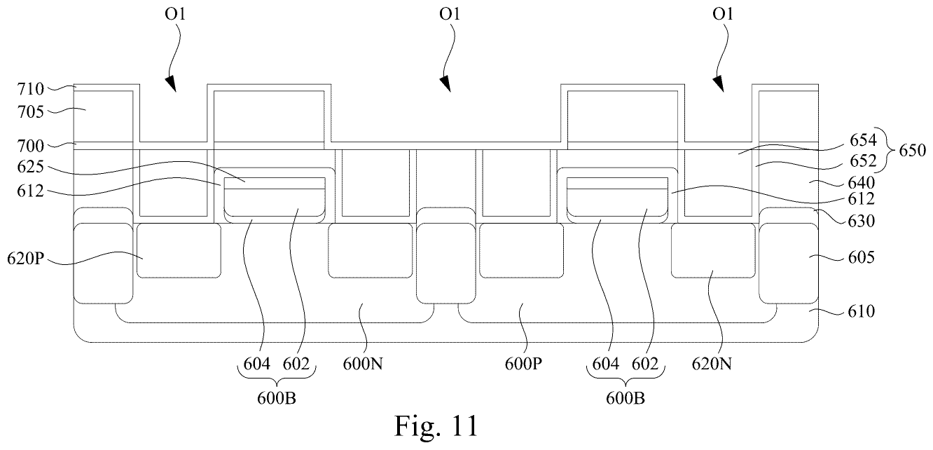

In FIG. 11, one or more liner layers 710 are conformally deposited into the trenches O1 by using physical vapor deposition (PVD), CVD, ALD, or the like. In some embodiments, the one or more liner layers 710 include a diffusion barrier layer and a copper (Cu) seed layer. The diffusion barrier layer includes a tantalum-containing material such as tantalum (Ta) or tantalum nitride (TaN), serving to protect the IMD layer 705 from metallic diffusion and poisoning from the subsequently formed copper layer.

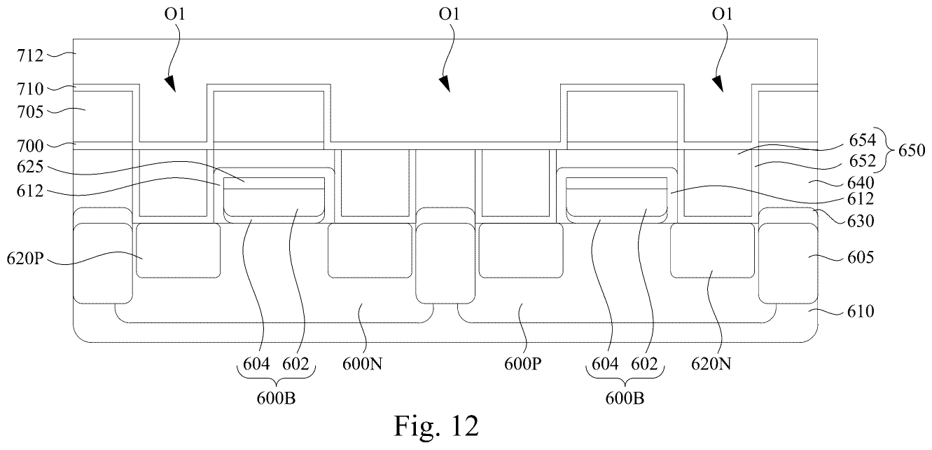

In FIG. 12 a fill metal layer 712 is deposited over the one or more liner layers 710 until the trenches O1 are overfilled with the fill metal layer 712. The fill metal layer 712 can be formed by electroplating a metal material over the one or more liner layers 710, followed by an annealing process performed on the metal material. In some embodiments, the fill metal layer 712 may be formed from a metal material such as copper, although other conductive materials such as nickel, gold, or metal alloy, combinations of these, or the like may also be used.

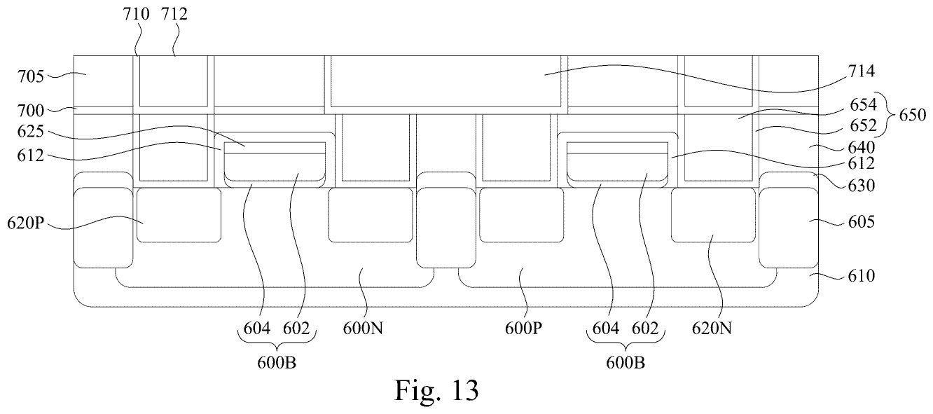

In FIG. 13, a planarization process, such as a chemical mechanical polishing (CMP) process, may be performed to remove excess metal materials of the fill metal layer 712 and the liner layers 710 from a top surface of the IMD layer 705, while leaving portions of the fill metal layer 712 and the liner layers 710 in the trenches O1 to serve as metal lines 714 embedded in the IMD layer 705.

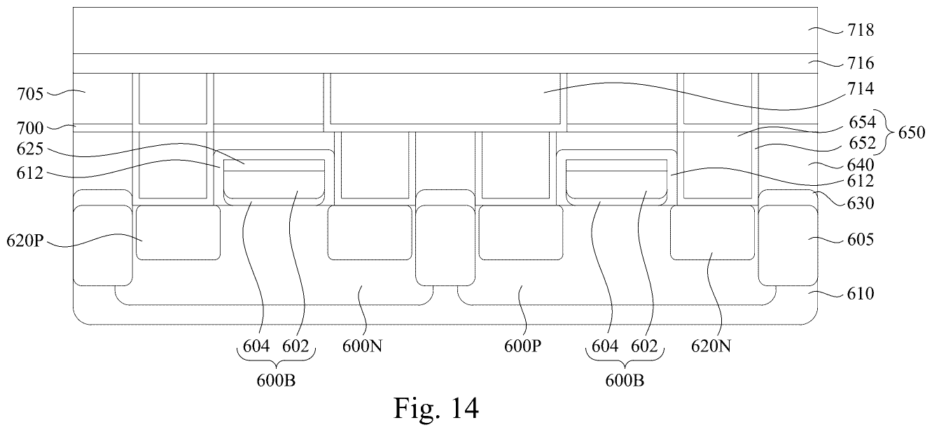

In FIG. 14, another ESL 716 and another IMD layer 718 are formed sequentially over the IMD layer 705. Materials and fabrication methods of ESL 716 are similar to that of the ESL 700, and thus are not repeated for the sake of brevity. Materials and fabrication methods of the IMD layer 718 are similar to that of the IMD layer 705, and thus are not repeated for the sake of brevity.

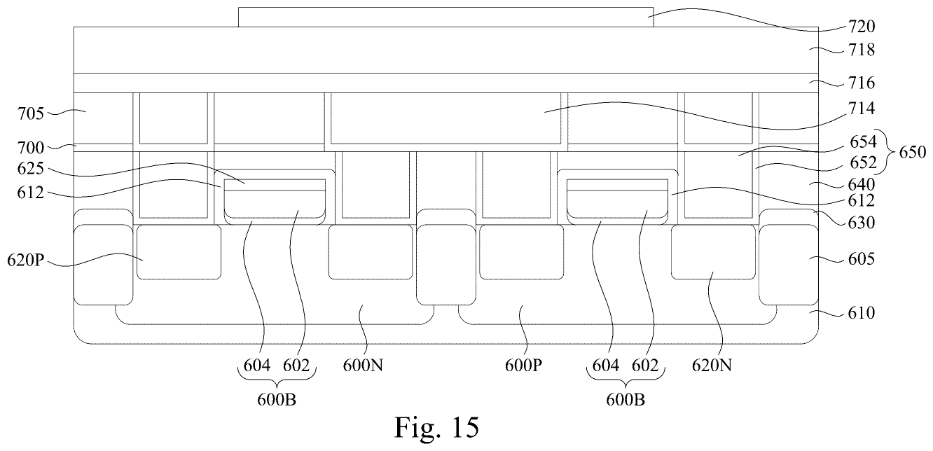

In FIG. 15, a back gate structure 720 is formed over the IMD layer 718. In some embodiments, the back gate structure 720 is formed by depositing one or more gate metal layers over the IMD layer 718, followed by patterning the one or more gate metal layers in to the back gate structure 720 using suitable photolithography and etching processes. In some embodiments, the back gate structure 720 includes TiN, TaN, Ti, Ta, Ru, Mo, Al, Ag, TaAl, TaAIC, TiAIN, TaC, TaCN, TaSiN, Mn, Zr, W, Co, the like, or combinations thereof. The materials used in forming the back gate structure 720 may be deposited by any suitable method, e.g., CVD, PECVD, PVD, ALD, PEALD, electrochemical plating (ECP), electroless plating, or the like.

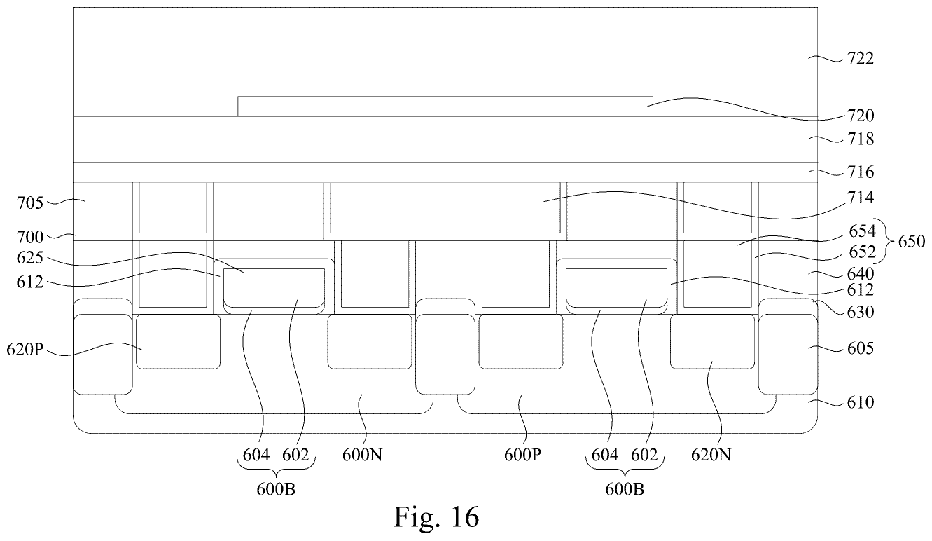

In FIG. 16, a high-k dielectric layer 722 is formed over the back gate structure 720 by using CVD, ALD or other suitable deposition techniques. The high-k dielectric layer 722 wraps around three sides of the back gate structure 720. In some embodiments, the high-k dielectric layer 722 has a dielectric constant greater than a dielectric constant of silicon oxide, about 3.9. The high-k dielectric layer 722 may include hafnium oxide (HfO₂). Alternatively, the high-k dielectric layer 722 may include other high-k dielectrics, such as hafnium silicon oxide (HfSiO), hafnium oxynitride (HfON), hafnium silicon oxynitride (HfSiON), hafnium tantalum oxide (HfTaO), hafnium titanium oxide (HfTiO), hafnium zirconium oxide (HfZrO), lanthanum oxide (La₂O₃), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

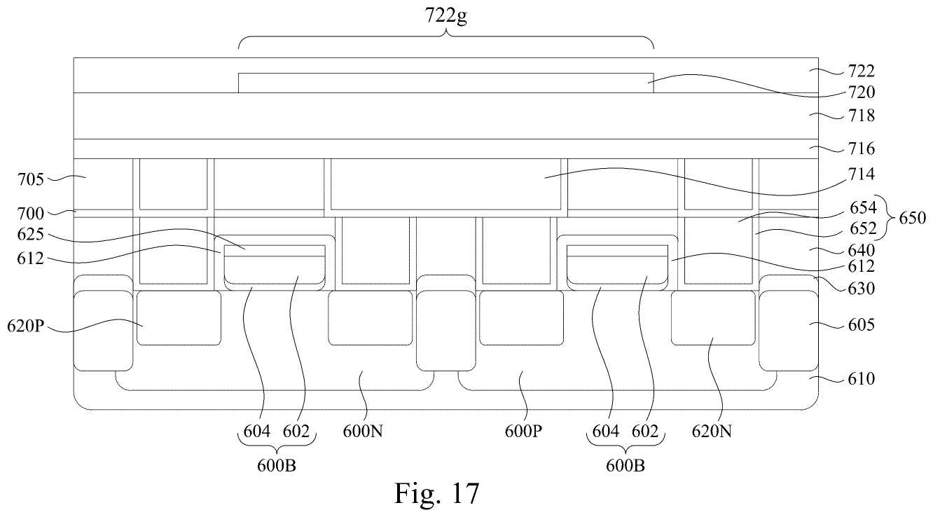

In FIG. 17, a planarization process, such as a CMP process, is performed to thin down the high-k dielectric layer 722 until a target thickness of the high-k dielectric layer 722 is achieved. After the CMP process is completed, a gate dielectric region 722g directly above the back gate structure 720 has a fine-tuned thickness suitable for serving as a gate dielectric for WSe₂-channel FETs. In some embodiments, the CMP process is a timed CMP process with a predetermined CMP duration time.

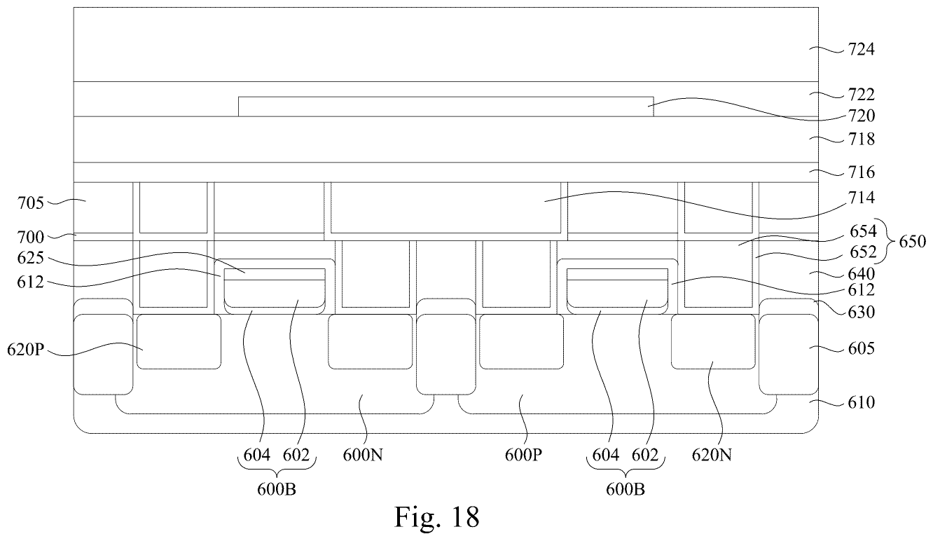

In FIG. 18, another ILD layer 724 is formed over the high-k dielectric layer 722. In some embodiments, the ILD layer 724 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 724 may be formed using, for example, CVD, ALD, spin-on-glass (SOG) or other suitable techniques.

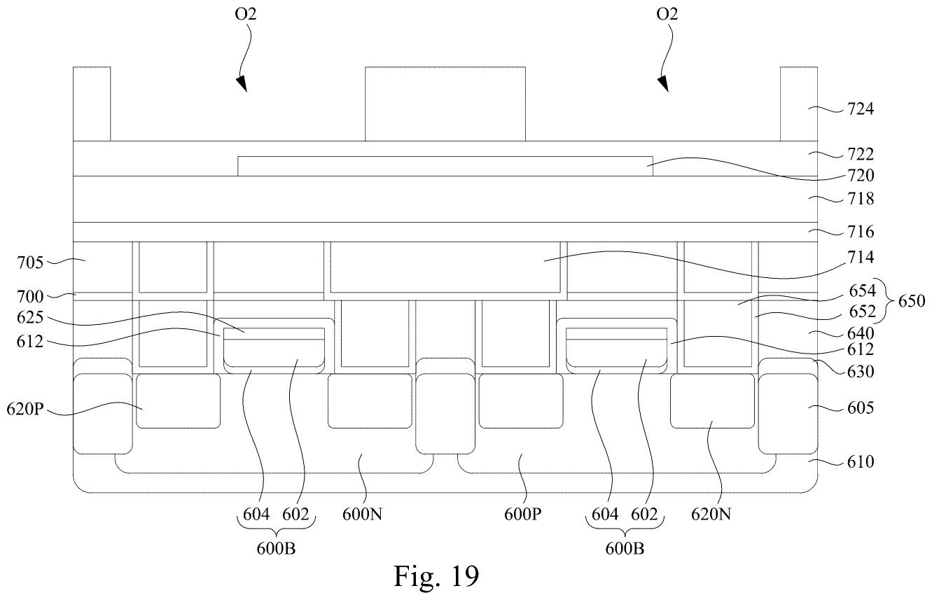

In FIG. 19, one or more openings O2 are formed in the ILD layer 724 by using suitable photolithography and etching techniques. The openings O2 serve to define patterns of subsequently formed WSe₂ layers. In some embodiments, the openings O2 vertically overlap with the back gate structure 720, which allows for controlling channel regions of the subsequently formed WSe₂ layers by using the back gate structure 720.

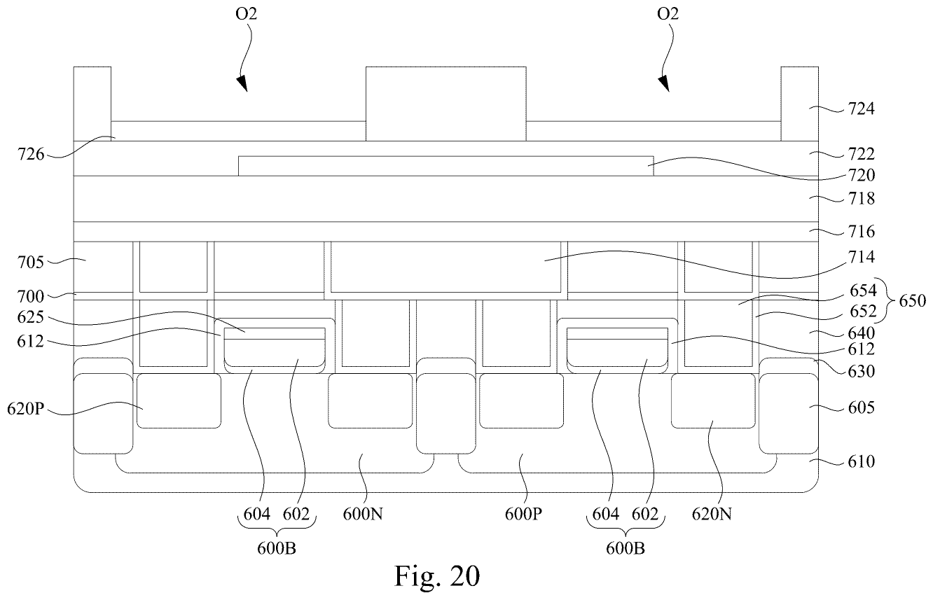

In FIG. 20, a plurality of transition metal layers 726 are formed in the openings O2, respectively. In some embodiments, the transition metal layers 726 can be formed by, for example, depositing a global transition metal layer over the substrate 610 until the openings O2 are overfilled with the global transition metal layer, followed by etching back the global transition metal layer, leaving the transition metal layers 726 localized to respective openings O2. In some embodiments, the global transition layer is etched back by using a selective etching process using etchant(s) etching the transition metal at a faster etching rate than etching the material of the ILD layer 724, such that the transition metal layers 726 have top surfaces lower than a top surface of the ILD layer 724. In some other embodiments, the transition metal layers 726 may be formed by a selective deposition process that deposits transition metal at a faster deposition rate over the high-k dielectric layer 722 than over the ILD layer 724. In some embodiments, the transition metal layers 726 are formed of transition metal including, for example, W, Mo, Pt, or other suitable transition metals that can be used to form TMD.

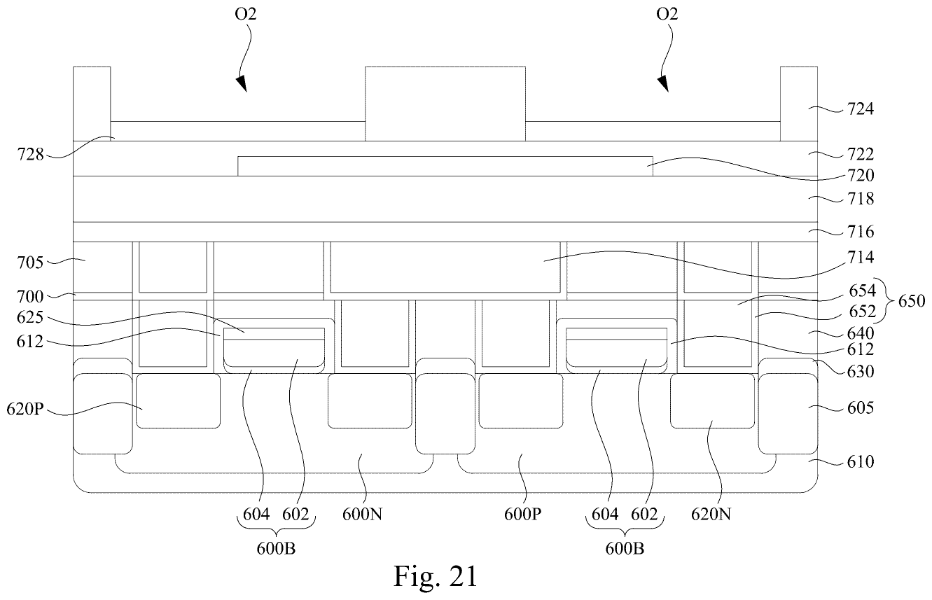

In FIG. 21, the transition metal layers 726 are converted into transition metal dichalcogenide (TMD) layers 728, interchangeably referred to as 2D semiconductor layers 728. For example, an annealing process can be performed using a sulfur-containing gas (e.g., H₂S) or a selenium-containing gas (H₂Se) as an ambient gas, thus sulfurizing or selenizing the transition metal layers 726 into TMD layers 728. For example, in some embodiments where the transition metal layers 726 are W, the annealing process performed using H₂Se results in a selenization reaction with W, thus forming WSe₂ to serve as TMD layers 728.

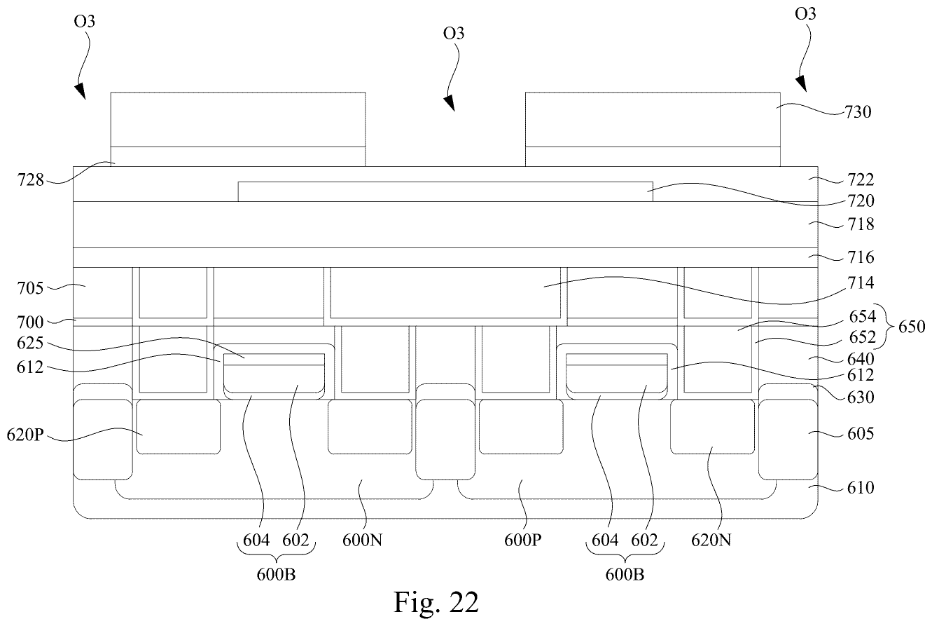

In FIG. 22, the ILD layer 724 is etched to form source/drain contact openings O3 extending through the ILD layer 724 to expose opposite side surfaces of the 2D semiconductor layers 728. In some embodiments, prior to etching the ILD layer 724, a patterned mask layer 730 is formed over the 2D semiconductor layers 728 to protect the 2D semiconductor layers 728 against etching processing. With the patterned mask layer 730 in place, the source/drain contact openings O3 are etched in the ILD layer 724 with no or negligible impact on the 2D semiconductor layers 728.

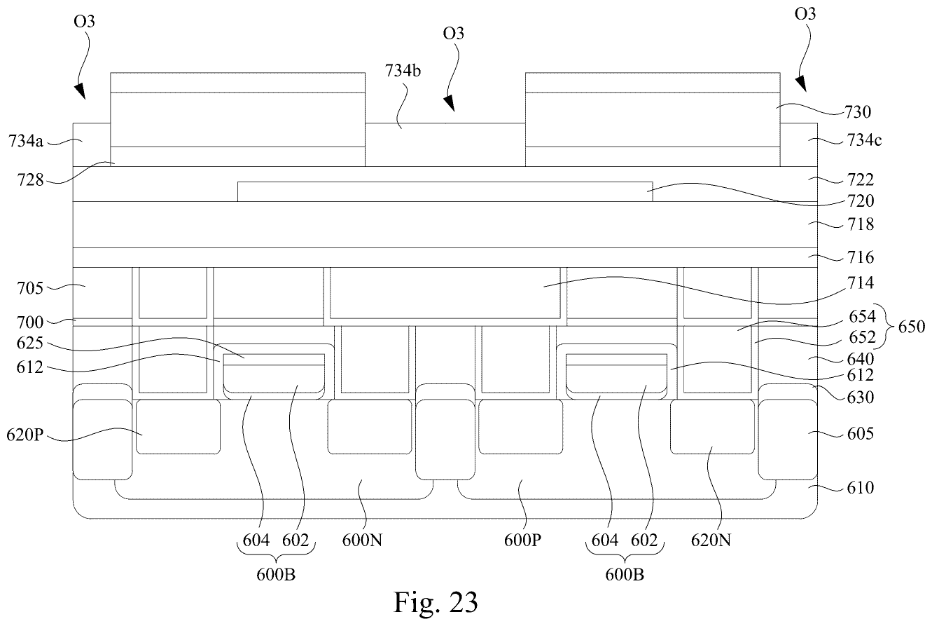

FIGS. 23-28A illustrate exemplary processing steps of forming multilayer source/drain contacts in the source/drain contact openings O3. These processing steps are merely exemplary, and are not intended to limit the present disclosure. In FIG. 23, first semimetal layers 734a, 734b, and 734c (collectively referred to as first semimetal layers 734) are deposited over the high-k dielectric layer 722 in the openings O3. In some embodiments, the first semimetal layer 110 is antimony (Sb). The deposition of antimony may be achieved through several techniques, such as PVD, CVD or molecular beam epitaxy (MBE).

Take PVD as an example, the first semimetal layer 110 can be deposited using an evaporation process. In the evaporation process, an antimony source is placed in an evaporation source holder inside a high-vacuum chamber. The source material is then heated to its sublimation point using either resistive heating or electron beam heating. Upon reaching the sublimation point, antimony atoms begin to evaporate from the source and travel in a line-of-sight path in the vacuum chamber. The substrate 610 with the high-k dielectric layer 722 is positioned above the antimony source and held at a cooler temperature to promote adhesion and condensation of the evaporating antimony atoms. A shutter may be used to control the deposition time and achieve the desired thickness of the antimony layer. The evaporated antimony atoms adhere to the top surface of the high-k dielectric layer 722 and the top surface of the patterned mask layer 730, forming the first semimetal layers 734.

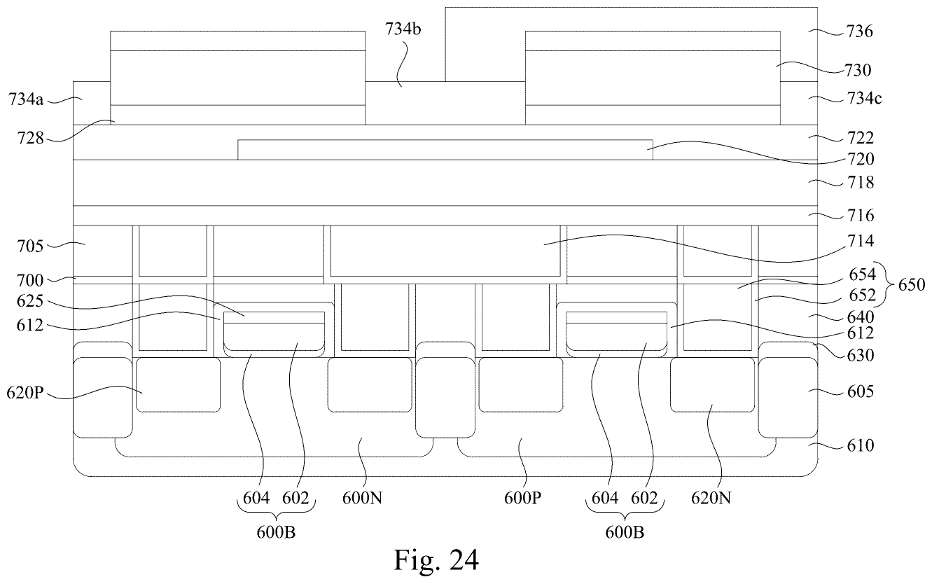

In FIG. 24, another patterned mask layer 736 is formed over an NFET region to cover the rightmost first semimetal layer 734c, and a right portion of the first semimetal layer 734b, while leaving the leftmost first semimetal layer 734a and a left portion of the first semimetal layer 734b exposed.

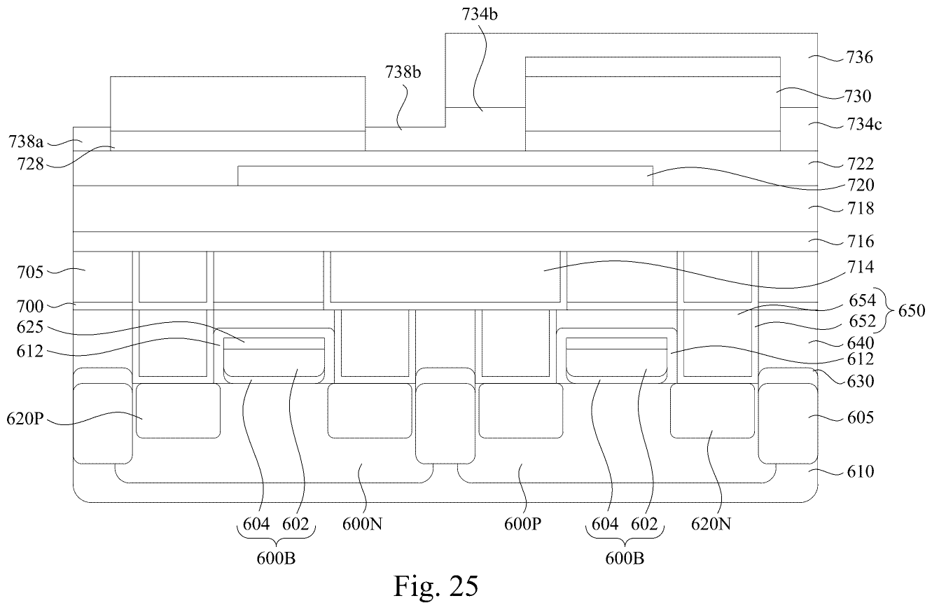

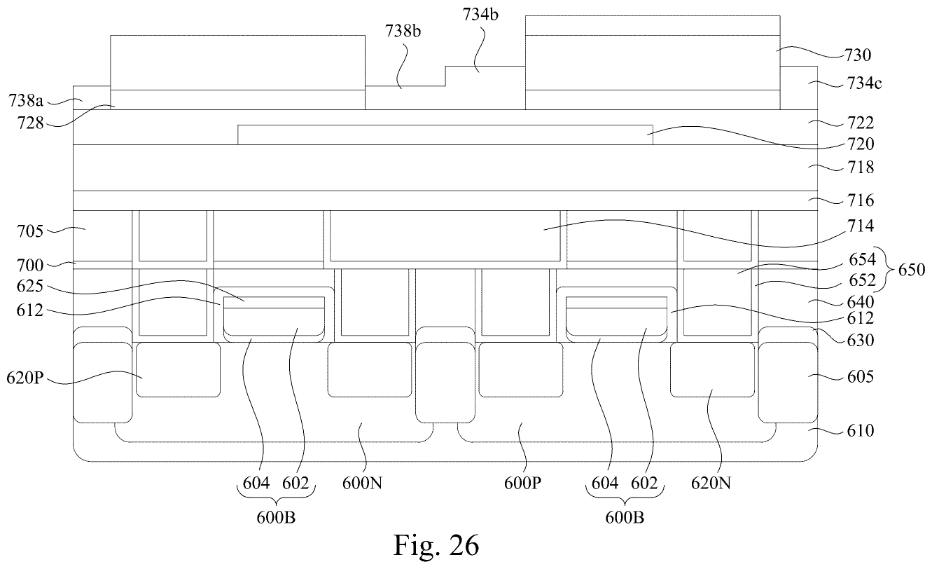

Next, the exposed leftmost first semimetal layer 734a and the exposed left portion of the first semimetal layer 734b are etched back by using the patterned mask layer 736 as an etch mask, resulting in a thinned-down first semimetal layer 738a and a thinned-down first semimetal portion 738b adjoining an un-thinned portion of first semimetal layer 734b, as illustrated in FIG. 25. The thinned-down semimetal region 738b and the un-thinned first semimetal portion 734b form a stepped top surface profile with a step height between a top surface of the thinned-down semimetal region 738b and a top surface of the un-thinned first semimetal portion 734b. In some embodiments, the step height is in a range from about 15 nm to about 25 nm (e.g., about 20 nm). In some embodiments, the thinned-down first semimetal layer 738a and the thinned-down first semimetal portion 738b have a thickness in a range from about 8 nm to about 12 nm (e.g., about 10 nm), and the un-thinned first semimetal portion 734b and the un-thinned first semimetal layer 734c have a thickness in a range from about 25 nm to about 35 nm (e.g., about 30 nm). This thickness difference allows for forming a PFET using the thinned-down first semimetal layer 738a and the thinned-down first semimetal portion 738b as basis of PFET's source/drain contacts, while forming an NFET using the un-thinned first semimetal portion 734b and the un-thinned first semimetal layer 738c as basis of NFET's source/drain contacts. Once the thickness difference is created, the patterned mask layer 736 is removed, as illustrated in FIG. 26.

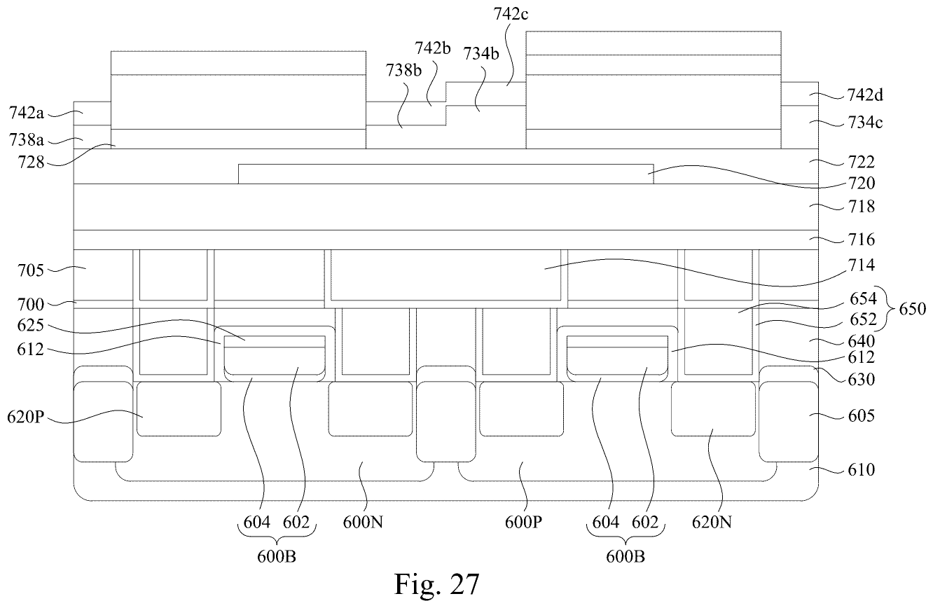

In FIG. 27, second semimetal layers 742a, 742b, 742c and 742d (collectively referred to as second semimetal layers 742) are respectively formed over the thinned-down first semimetal layers 738a, 738b, and un-thinned first semimetal layers 734b, 734c. In some embodiments, the second semimetal layers 742 are platinum (Pt) and have a thickness in a range from about 10 nm to about 15 nm (e.g., about 12 nm). The deposition of platinum may be achieved through several techniques, such as PVD or CVD. Take PVD as an example, the second semimetal layers 742 can be deposited using evaporation. In a platinum evaporation process, a platinum source is placed in an evaporation boat or crucible within a high-vacuum chamber. The platinum source is then subjected to heating, such as using resistive or electron beam heating, until it reaches its evaporation temperature. As the platinum atoms evaporate, they travel in a line-of-sight path within the vacuum chamber towards the substrate 610. The substrate 610, which already includes the thinned-down first semimetal layers 738a, 738b and the un-thinned first semimetal layers 734b, 734c, is positioned at a distance above the platinum source. The substrate 610 is kept at a cooler temperature to promote the condensation and adhesion of the evaporated platinum atoms. A shutter mechanism may be used to control the exposure time, allowing for precise control over the thickness of the platinum layer. The evaporated platinum atoms adhere to the thinned-down first semimetal layers 738a, 738b and the un-thinned first semimetal layers 734b, 734c, forming the second semimetal layers 742.

In some embodiments where antimony constitutes the first semimetal layers 734b, 734c, and the thinned-down first semimetal layers 738a, 738b, the phenomenon of re-sublimation of antimony may be observed during the deposition of platinum for the second semimetal layers 742. This is attributed to the fact that antimony has a lower sublimation temperature compared to platinum. During the evaporation process for platinum deposition, the chamber's environment is subjected to temperatures exceeding the sublimation point of antimony. As a consequence, there may be a reduction in the thicknesses of the pre-existing first semimetal layers 734b, 734c, as well as the thinned-down layers 738a, 738b. Furthermore, given the sublimation of antimony during the platinum deposition, a compositional intermingling is possible. Specifically, a mixture of re-sublimated antimony atoms and evaporated platinum atoms may collectively adhere to the surface of the underlying first semimetal layers. This may result in second semimetal layers 742 having a heterogenous composition of Sb—Pt alloy.

In some embodiments, because the top surfaces of the un-thinned first semimetal layers 734b, 734c are higher than the top surfaces of the thinned-down first semimetal layers 738a, 738b, top surfaces of the second semimetal layer 742c and 742d may be higher than top surfaces of the second semimetal layers 742a and 742b.

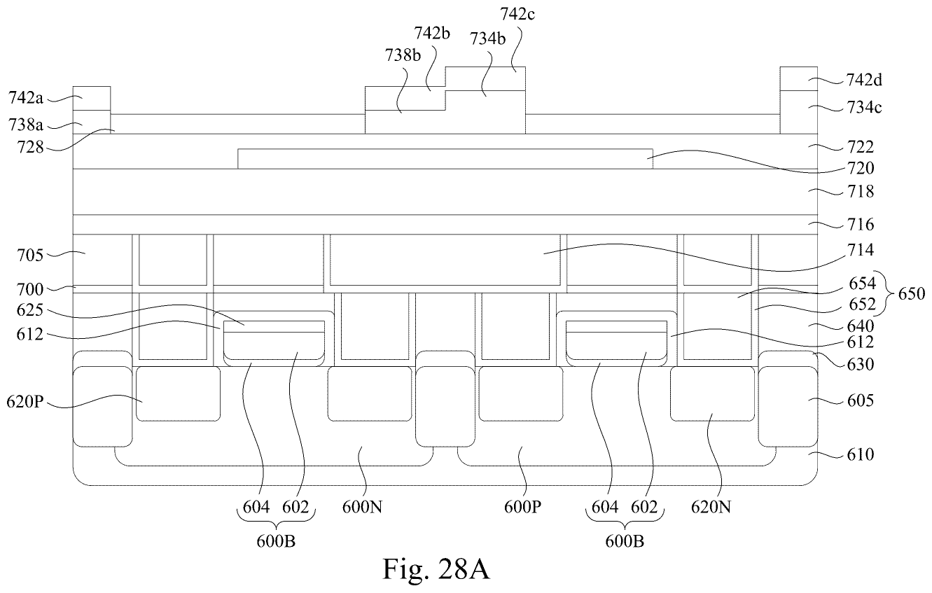

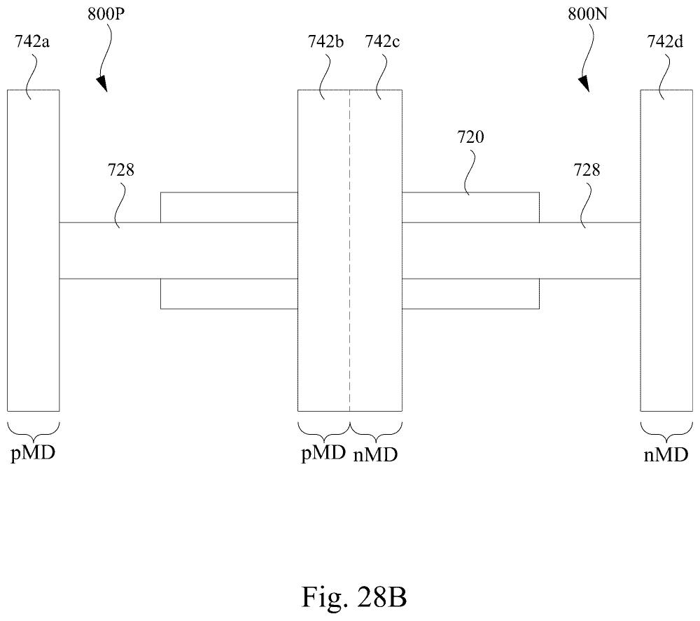

In FIGS. 28A and 28B, the patterned mask layer 730 is removed by using, for example, a lift-off process. Lifting off the patterned mask layer 730 also removes any overlying materials of the first and second semimetal layers. The resulting structure includes an NFET 800N and a PFET 800P sharing a common back gate structure 720, which in turn collectively serves as a complementary FET (CFET) structure. The PFET 800P includes a first PFET source/drain contact comprising a stack of first semimetal layer 738a and second semimetal layer 742a, and a second PFET source/drain contact comprising a stack of first semimetal layer 738b and second semimetal layer 742b. The NFET 800N includes a first NFET source/drain contact comprising a stack of first semimetal layer 734b and second semimetal layer 742c, and a second NFET source/drain contact comprising a stack of first semimetal layer 734c and second semimetal layer 742d.

In some embodiments, the NFET source/drain contacts each includes a thickness ratio of Sb to Pt (i.e., thickness ratio of first semimetal layer to second semimetal layer) exceeding 100%, allowing for the WSe₂-channel FET primarily functioning as an NFET, as discussed in detail above. In some embodiments, the PFET source/drain contacts each includes a thickness ratio of Sb to Pt (i.e., thickness ratio of first semimetal layer to second semimetal layer) less than 100%, allowing for the WSe₂-channel FET primarily functioning as a PFET, as discussed in detail above. In such scenarios, the NFET source/drain contact has a thicker first semimetal layer than the PFET source/drain contact, but a second semimetal layer having a same thickness as that of the PFET source/drain contact. Therefore, the NFET source/drain contact has a higher top surface than the PFET source/drain contact.

FIG. 28B is an example top view of the structure in FIG. 28A. As illustrated in FIG. 28B, the PFET source/drain contacts, labeled “pMD” in FIG. 28B, have a strip-shaped top-view patterns extending in a direction perpendicular to a longitudinal direction of a top-view pattern of a 2D semiconductor layer 728. The PFET source/drain contacts pMD are in contact with opposite side surfaces of the 2D semiconductor layer 728. Similarly, the NFET source/drain contacts, labeled “nMD” in FIG. 28B, have a strip-shaped top-view patterns extending in a direction perpendicular to a longitudinal direction of a top-view pattern of another 2D semiconductor layer 728. The NFET source/drain contacts nMD are in contact with opposite side surfaces of the 2D semiconductor layer 728. In some embodiments, a PFET source/drain contact pMD has a longitudinal side in contact with a longitudinal side of an NFET source/drain contact nMD.

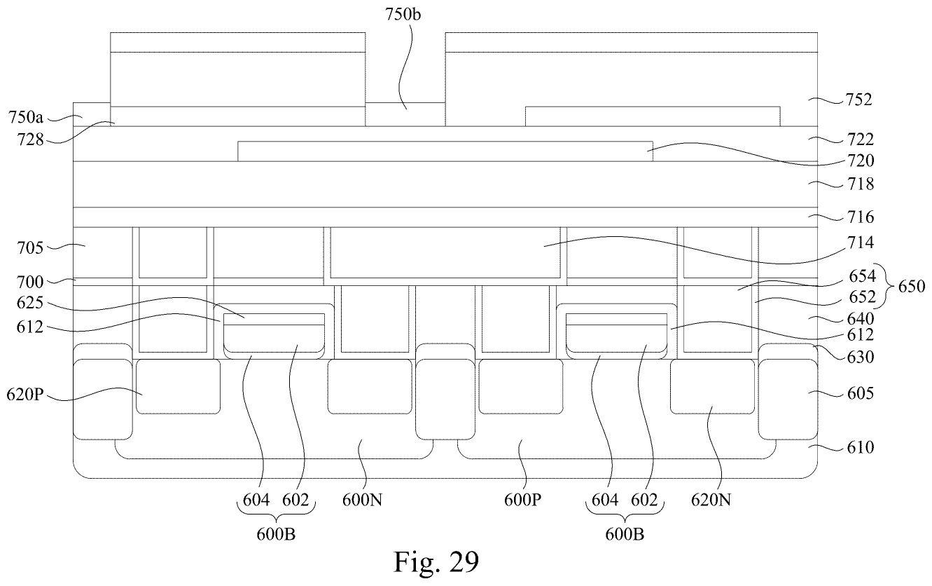

FIGS. 29-33 illustrate exemplary processing steps of forming multilayer source/drain contacts in the source/drain contact openings O3, in accordance with some other embodiments. These processing steps are merely exemplary, and are not intended to limit the present disclosure. In FIG. 29, thinner first semimetal layers 750a and 750b are deposited over PFET region, with a patterned mask layer 752 masking the NFET region.

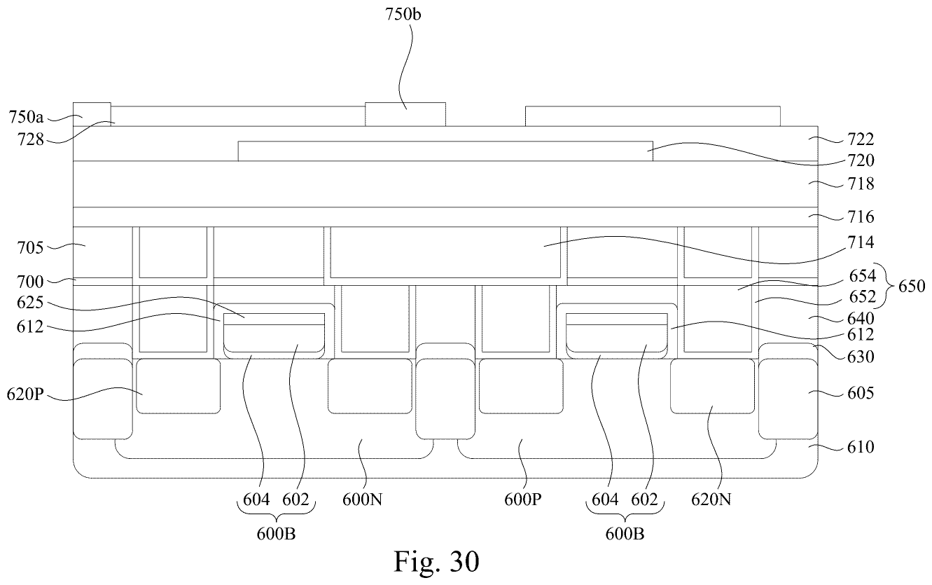

In FIG. 30, the patterned mask layer 752 is removed by using, for example, a lift-off process. Lifting off the patterned mask layer 752 also removes any overlying materials of the thinner first semimetal layer.

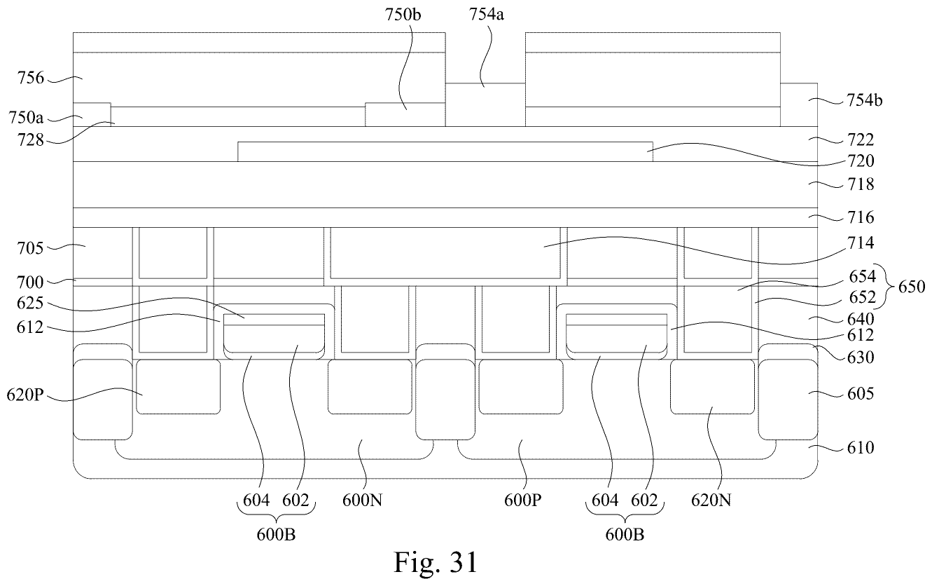

In FIG. 31, thicker first semimetal layers 754a and 754b are deposited over NFET region, with a patterned mask layer 756 masking the PFET region. In some embodiments, the thicker first semimetal layers 754a and 754b have a greater thickness than the thinner first semimetal layers 750a and 750b, such that the adjoining first semimetal layers 750b and 754a form a stepped top surface profile with a step height between a top surface of the thinner first semimetal layer 750b and a top surface of the thicker first semimetal layer 754a. In some embodiments, the step height is in a range from about 15 nm to about 25 nm (e.g., about 20 nm). In some embodiments, the thinner first semimetal layers 750a and 750b have a thickness in a range from about 8 nm to about 12 nm (e.g., about 10 nm), and the thicker first semimetal layers 754a and 754b have a thickness in a range from about 25 nm to about 35 nm (e.g., about 30 nm). This thickness difference allows for forming a PFET using the thinner first semimetal layers 750a and 750b as basis of PFET's source/drain contacts, while forming an NFET using the thicker first semimetal layers 754a and 754b as basis of NFET's source/drain contacts.

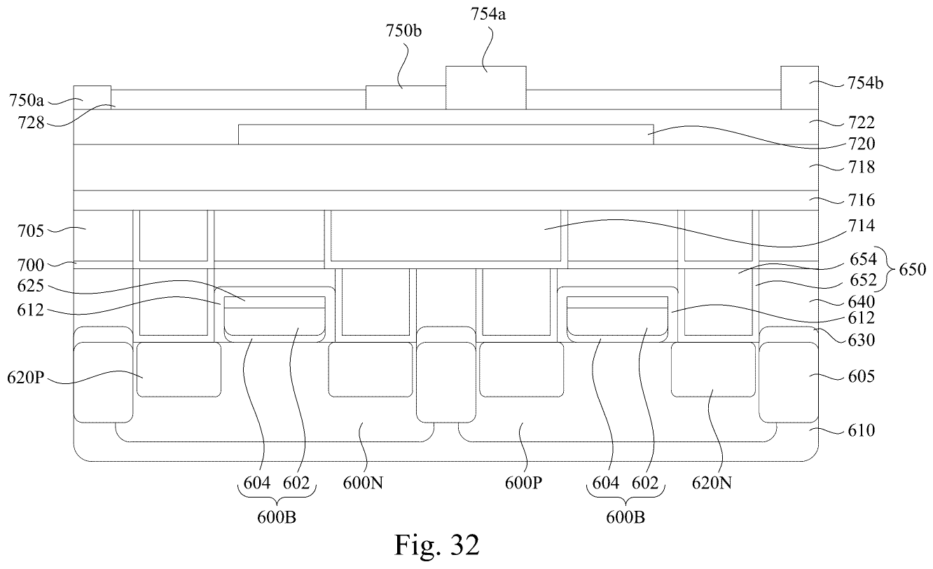

In FIG. 32, the patterned mask layer 756 is removed by using, for example, a lift-off process. Lifting off the patterned mask layer 756 also removes any overlying materials of the thicker first semimetal layer.

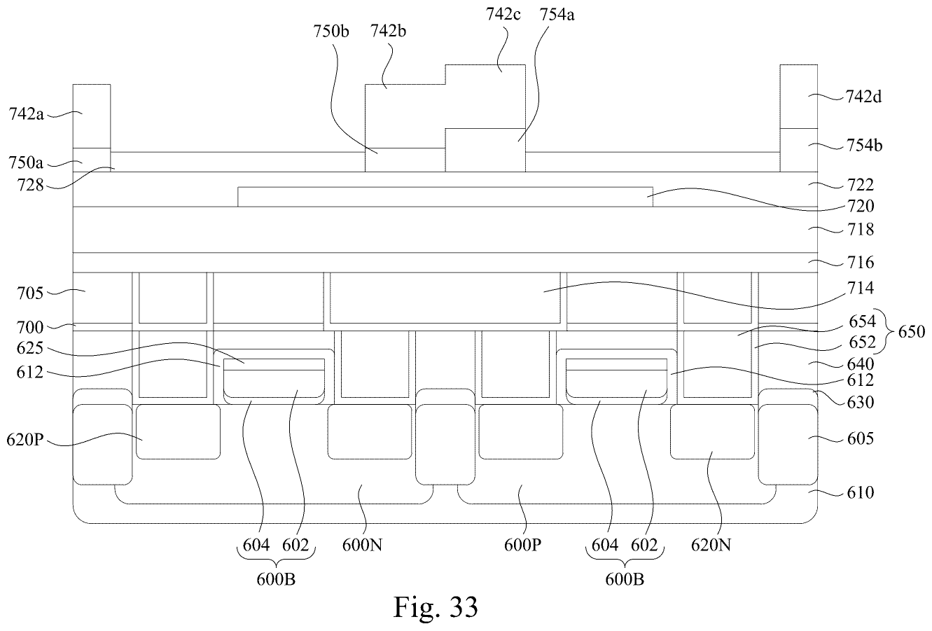

In FIG. 33, second semimetal layers 742a, 742b, 742c and 742d (collectively referred to as second semimetal layers 742) are respectively formed over the thinner first semimetal layers 750a and 750b and the thicker first semimetal layers 754a and 754b. In some embodiments, the 2D semiconductor layers 728 are covered with a patterned mask layer prior to forming the second semimetal layers 742. After formation of the second semimetal layers 742 are completed, the patterned mask layer is removed by using a lift-off process. In some embodiments, the second semimetal layers 742 are platinum (Pt) and have a thickness in a range from about 10 nm to about 15 nm (e.g., about 12 nm). The deposition of platinum may be achieved through several techniques, such as PVD or CVD, as discussed previously with respect to FIG. 27.

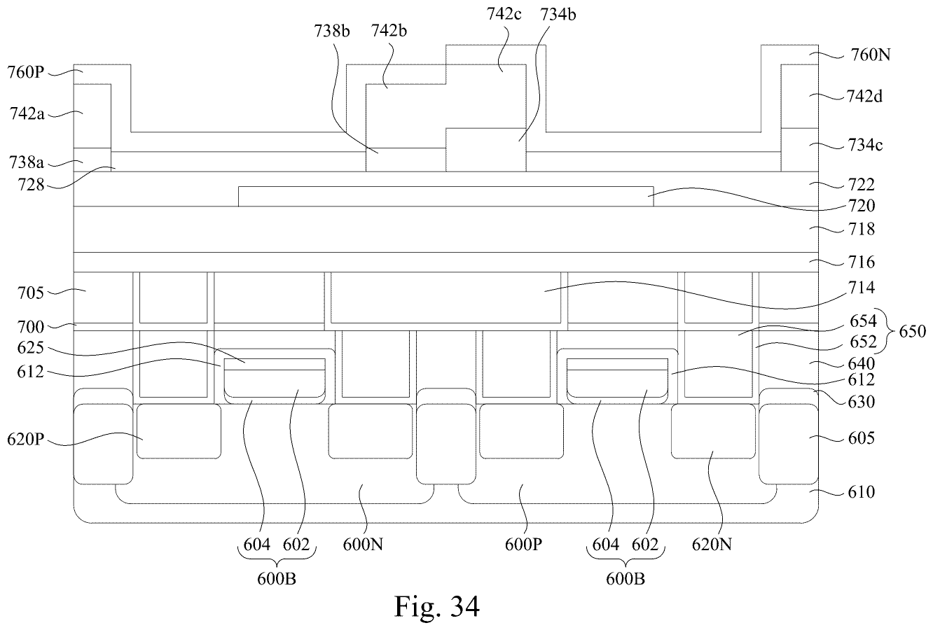

FIG. 34 illustrates an exemplary cross sectional view of semiconductor devices according to some other embodiments of the present disclosure. FIG. 34 shows substantially the same structure as FIG. 28A or FIG. 33, except that a p-type drain-current improvement layer 760P is formed over the PFET source/drain contacts each including a thinned first semimetal layer 738 and a second semimetal layer 742, and an n-type drain-current improvement layer 760N is formed over the NFET source/drain contacts each including an un-thinned first semimetal layer 734 and a second semimetal layer 742. The p-type drain-current improvement layer 760P and the n-type drain-current improvement layer 760N are formed in respective deposition and patterning processes. For example, in some embodiments, the p-type drain-current improvement layer 760P is formed by globally depositing a blanket layer spanning across both NFET region and PFET region, followed by patterning the blanket layer into the p-type drain-current improvement layer 760P localized to the PFET region. Similarly, the n-type drain-current improvement layer 760N is formed by globally depositing a blanket layer spanning across both NFET region and PFET region, followed by patterning the blanket layer into the n-type drain-current improvement layer 760N localized to the NFET region.

The p-type drain-current improvement layer 760P has a material suitable for increasing drain current when the WSe₂-channel FET is operate under PFET mode (i.e., under negative gate voltage conditions). In some embodiments, the p-type drain-current improvement layer 760P is a molybdenum oxide (MoOₓ) layer, a nitrogen dioxide (NO₂) layer, an tungsten oxide (WOₓ) layer, a iodine (I₂) layer, combinations thereof, or the like, which is deposited over the PFET source/drain contacts and the 2D semiconductor layer 728 extending between the PFET source/drain contacts by using suitable deposition technique such as CVD, plasma-enhanced CVD (PECVD), atomic layer deposition (ALD), or the like. In some embodiments, the p-type drain-current improvement layer 760P has a thickness in a range from about 1 nm to 50 nm.

The n-type drain-current improvement layer 760N has a material suitable for increasing drain current when the WSe₂-channel FET is operate under NFET mode (i.e., under positive gate voltage conditions). In some embodiments, the n-type drain-current improvement layer 760N is a silicon oxynitride (SiONₓ) layer, a hafnium oxide (HfOₓ) layer, an aluminum oxide (AlOₓ) layer, a titanium oxide (TiOₓ) layer, combinations thereof, or the like, which is deposited over the NFET source/drain contacts and the 2D semiconductor layer 728 extending between the NFET source/drain contacts by using suitable deposition technique such as CVD, plasma-enhanced CVD (PECVD), atomic layer deposition (ALD), or the like. In some embodiments, the n-type drain-current improvement layer 114N has a thickness in a range from about 1 nm to 50 nm.

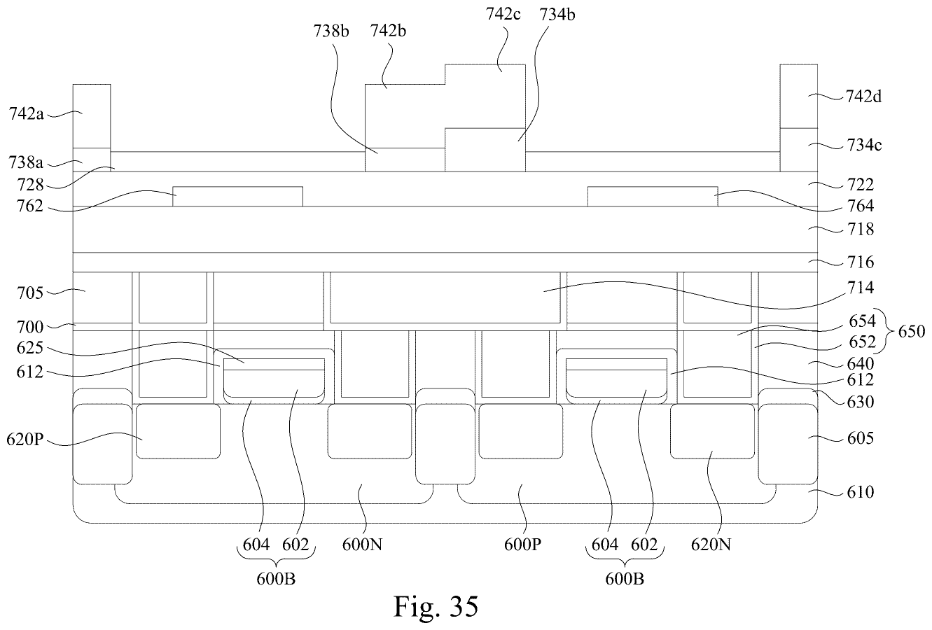

FIG. 35 illustrates an exemplary cross sectional view of semiconductor devices according to some other embodiments of the present disclosure. FIG. 35 shows substantially the same structure as FIG. 28A or FIG. 33, except that the common back gate structure 720 is replaced with two separate back gate structures 762 and 764. The back gate structures 762 and 764 are respectively localized within PFET region and NFET region, so that the PFET and NFET can be independently controlled by different back gate structures 762 and 764. In particular, the back gate structure 762 is laterally between the PFET source/drain contacts and vertically overlaps with the 2D semiconductor layer 728 that extends between the PFET source/drain contacts, and the back gate structure 764 is laterally between the NFET source/drain contacts and vertically overlaps with the 2D semiconductor layer 728 that extends between the NFET source/drain contacts. The separated back gate structures 762 and 764 can be formed at the step as illustrated in FIG. 15 by using suitable photolithography and etching techniques.

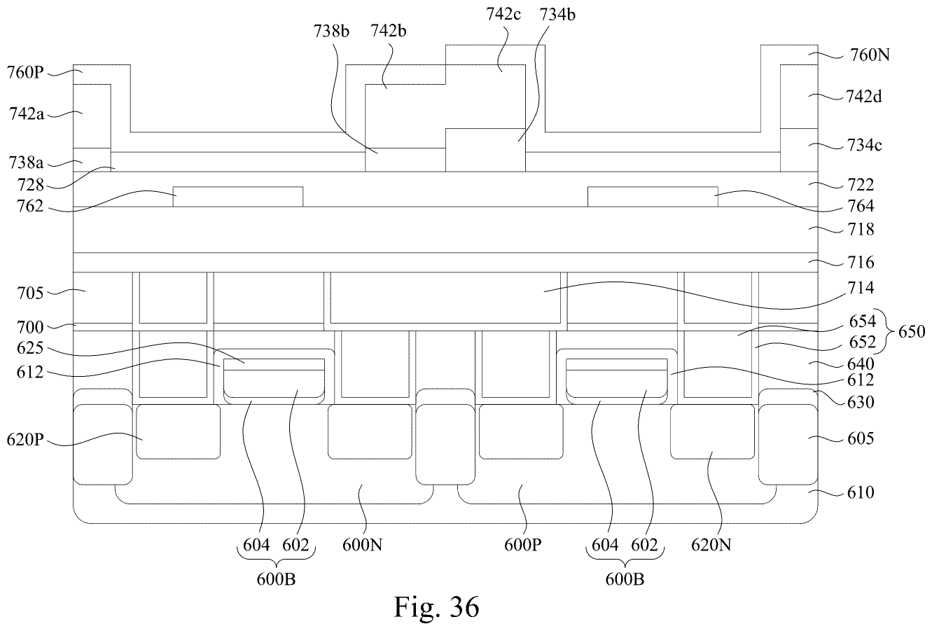

FIG. 36 illustrates an exemplary cross sectional view of semiconductor devices according to some other embodiments of the present disclosure. FIG. 36 shows substantially the same structure as FIG. 35, except that a p-type drain-current improvement layer 760P is formed over the PFET source/drain contacts each including a thinned first semimetal layer 738 and a second semimetal layer 742, and an n-type drain-current improvement layer 760N is formed over the NFET source/drain contacts each including an un-thinned first semimetal layer 734 and a second semimetal layer 742. The p-type drain-current improvement layer 760P vertically overlaps an entirety of the back gate structure 762, and n-type drain-current improvement layer 760N vertically overlaps an entirety of the back gate structure 764. Example materials and other details about the drain-current improvement layers 760P and 760N are discussed previously with respect to FIG. 34, and thus they are not repeated herein for the sake of brevity.

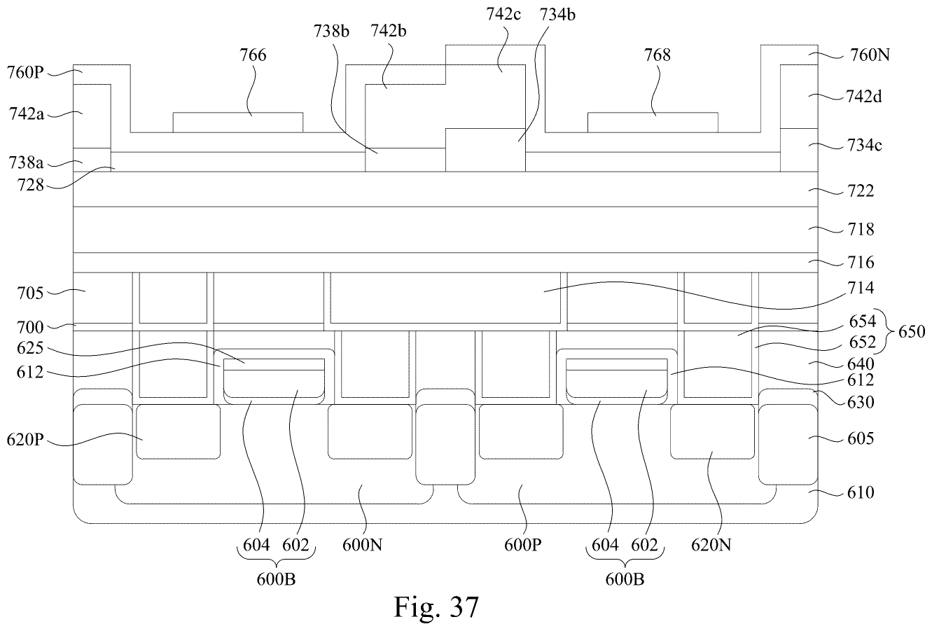

FIG. 37 illustrates an exemplary cross sectional view of semiconductor devices according to some other embodiments of the present disclosure. FIG. 37 shows substantially the same structure as FIG. 36, except that the back gate structures 762 and 764 are replaced with front gate structures 766 and 768, which are respectively formed over the p-type drain-current improvement layer 760P and the n-type drain-current improvement layer 760N. In some embodiments where the p-type drain-current improvement layer 760P and the n-type drain-current improvement layer 760N are dielectric materials, they can serve as gate dielectrics for spacing apart the front gate structures 766 and 768 from the underlying 2D semiconductor materials 728. In some embodiments, the front gate structures 766 and 768 are formed by, for example, deposing one or more gate metal layers over the p-type drain-current improvement layer 760P and the n-type drain-current improvement layer 760N, followed by patterning the one or more gate metal layers into the front gate structures 766 and 768.

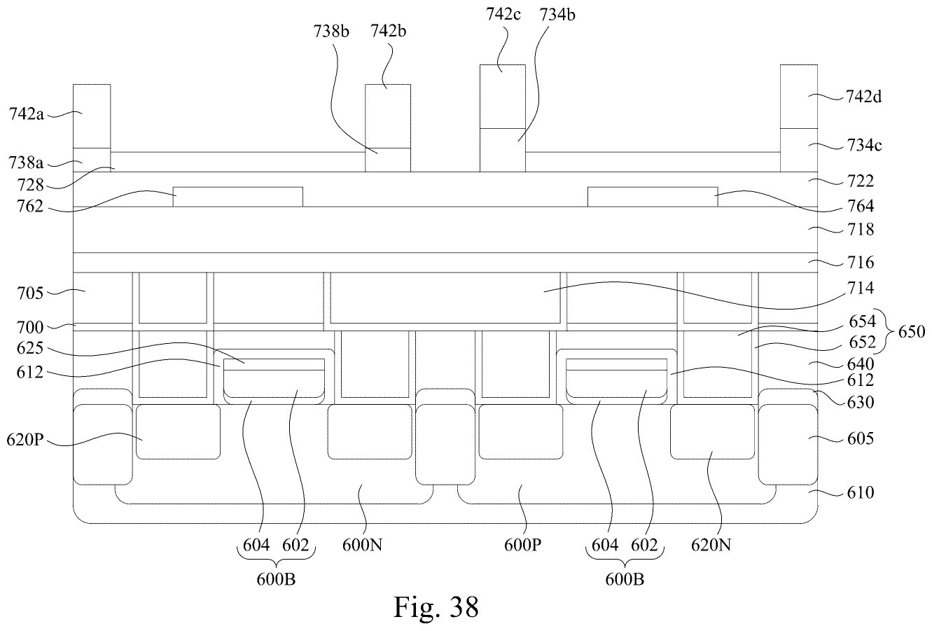

FIG. 38 illustrates an exemplary cross sectional view of semiconductor devices according to some other embodiments of the present disclosure. FIG. 38 shows substantially the same structure as FIG. 35, except that the PFET source/drain contact comprising the semimetal layers 738b and 742b is spaced apart from the adjacent NFET source/drain contact comprising the semimetal layers 734b and 742c. As a result, the NFET and the PFET are free of shared source/drain contacts in this embodiment. This structure cam be formed by, for example, performing an etching process on the structure as illustrated in FIG. 35 to etch through the semimetal layers 742b, 742c, 738b and 734b, resulting in separated source/drain contacts.

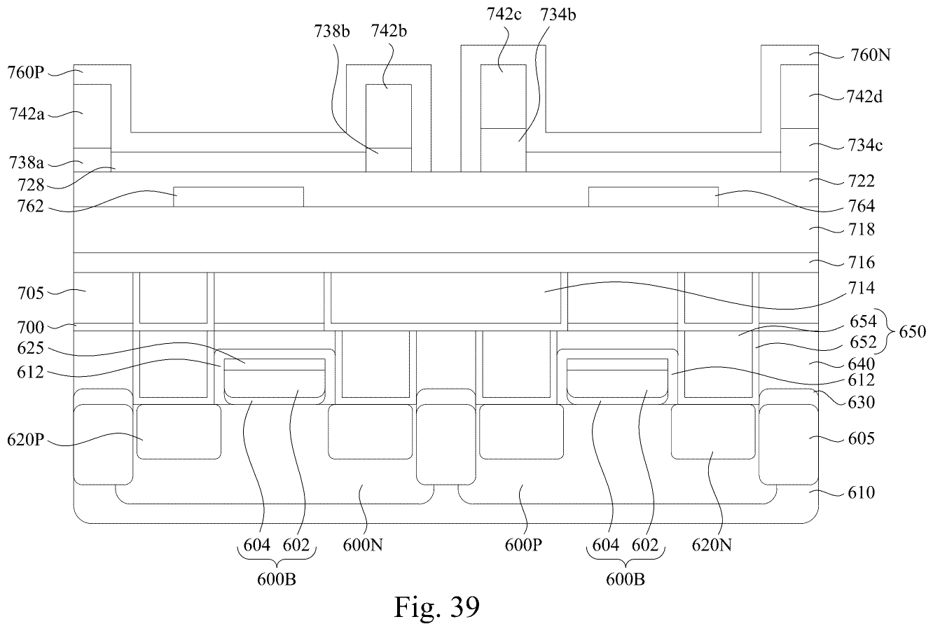

FIG. 39 illustrates an exemplary cross sectional view of semiconductor devices according to some other embodiments of the present disclosure. FIG. 39 shows substantially the same structure as FIG. 38, except that a p-type drain-current improvement layer 760P is formed over the PFET source/drain contacts each including a thinned first semimetal layer 738 and a second semimetal layer 742, and an n-type drain-current improvement layer 760N is formed over the NFET source/drain contacts each including an un-thinned first semimetal layer 734 and a second semimetal layer 742. The p-type drain-current improvement layer 760P is in contact with outermost sidewalls of the semimetal layers 738b and 742b that face the NFET region. The n-type drain-current improvement layer 760N is in contact with outermost sidewalls of the semimetal layers 734b and 742c that face the PFET region. Example materials and other details about the drain-current improvement layers 760P and 760N are discussed previously with respect to FIG. 34, and thus they are not repeated herein for the sake of brevity.

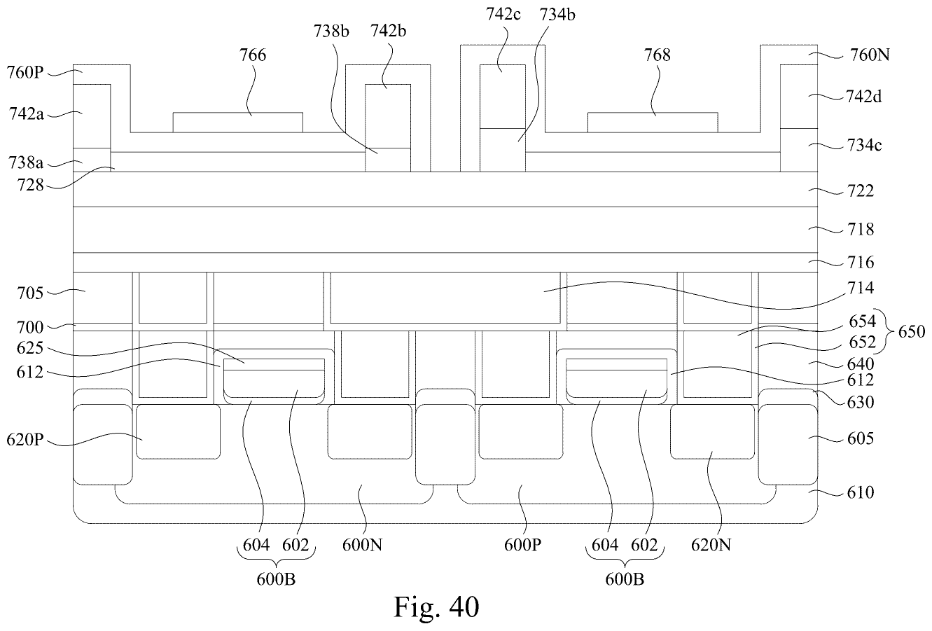

FIG. 40 illustrates an exemplary cross sectional view of semiconductor devices according to some other embodiments of the present disclosure. FIG. 40 shows substantially the same structure as FIG. 39, except that the back gate structures 762 and 764 are replaced with front gate structures 766 and 768, which are respectively formed over the p-type drain-current improvement layer 760P and the n-type drain-current improvement layer 760N. In some embodiments where the p-type drain-current improvement layer 760P and the n-type drain-current improvement layer 760N are dielectric materials, they can serve as gate dielectrics for spacing apart the front gate structures 766 and 768 from the underlying 2D semiconductor materials 728.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that Sb—Pt contacts mitigate the Fermi level pinning issues commonly encountered in 2D semiconductor devices when Pd contacts are used. Another advantage is that effective work function of the Sb—Pt contacts is tunable by varying the thickness ratio between the Sb and Pt layers, thereby advantageously improving the performance of both PFETs and NFETs.

In some embodiments, a device includes an NFET and a PFET. The NFET includes a first two-dimensional (2D) semiconductor layer and first source/drain contacts on opposite sides of the first 2D semiconductor layer. The PFET includes a second 2D semiconductor layer and second source/drain contacts on opposite sides of the second 2D semiconductor layer. Each of the first source/drain contacts includes a first semimetal layer and a second semimetal layer over the first semimetal layer. Each of the second source/drain contacts includes a third semimetal layer and a fourth semimetal layer over the third semimetal layer. A thickness ratio of the first semimetal layer to the second semimetal layer in the NFET is greater than a thickness ratio of the third semimetal layer to the fourth semimetal layer in the PFET. In some embodiments, the first semimetal layer and the third semimetal layer comprise a same material. In some embodiments, the first semimetal layer is an antimony layer, and the third semimetal layer is an antimony layer. In some embodiments, the second semimetal layer and the fourth semimetal layer comprise a same material. In some embodiments, the second semimetal layer is a platinum layer, and the fourth semimetal layer is a platinum layer. In some embodiments, the thickness ratio of the first semimetal layer to the second semimetal layer in the NFET is greater than 100%. In some embodiments, the thickness ratio of the third semimetal layer to the fourth semimetal layer in the PFET is less than 100%. In some embodiments, the device further includes a first capping layer capping the first source/drain contacts of the NFET, and a second capping layer capping the second source/drain contacts of the PFET. The first capping layer and the second capping layer are formed of different materials. In some embodiments, the first capping layer is formed of silicon oxynitride, hafnium oxide, aluminum oxide, or titanium oxide. In some embodiments, the second capping layer is formed of molybdenum oxide, nitrogen dioxide, tungsten oxide, or iodine.

In some embodiments, a device includes a first 2D semiconductor layer over a substrate, a first source/drain contact interfacing a first region of the first 2D semiconductor layer, and a second source/drain contact interfacing a second region of the first 2D semiconductor layer spaced apart from the first region of the first 2D semiconductor layer. The first source/drain contact includes a first antimony layer interfacing the first region of the first 2D semiconductor layer, and a first platinum layer over the first antimony layer. In some embodiments, the first antimony layer has a thickness less than a thickness the first platinum layer. In some embodiments, the first antimony layer has a thickness greater than twice a thickness of the first platinum layer. In some embodiments, the device further includes a second 2D semiconductor layer over the substrate, a third source/drain contact interfacing a first region of the second 2D semiconductor layer, and a fourth source/drain contact interfacing a second region of the second 2D semiconductor layer. The third source/drain contact includes a second antimony layer and a second platinum layer over the second antimony layer. The first antimony layer and the second antimony layer have different thicknesses, and the first platinum layer and the second platinum layer have a same thickness.

In some embodiments, a method includes forming a dielectric layer over a substrate; forming a first 2D semiconductor layer and a second 2D semiconductor layer over the dielectric layer; forming a first antimony layer and a second antimony layer in contact with opposite sides of the first 2D semiconductor layer; forming a third antimony layer and a fourth antimony layer in contact with opposite sides of the second 2D semiconductor layer; and forming a first platinum layer, a second platinum layer, a third platinum layer, and a fourth platinum layer over the first antimony layer, the second antimony layer, the third antimony layer, and the fourth antimony layer, respectively. The third antimony layer has a thickness greater than a thickness of the first antimony layer. In some embodiments, forming the first 2D semiconductor layer and the second 2D semiconductor layer includes forming a first transition metal layer and a second transition metal layer over the dielectric layer, and selenizing the first transition metal layer and the second transition metal layer into the first 2D semiconductor layer and the second 2D semiconductor layer. In some embodiments, the method further includes forming a back gate structure over the substrate. The dielectric layer is formed over the back gate structure. In some embodiments, the fourth antimony layer has a thickness greater than a thickness of the second antimony layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an n-type field effect transistor (NFET) comprising a first two-dimensional (2D) semiconductor layer and first source/drain contacts on opposite sides of the first 2D semiconductor layer; and
a p-type field effect transistor (PFET) comprising a second 2D semiconductor layer and second source/drain contacts on opposite sides of the second 2D semiconductor layer,
wherein each of the first source/drain contacts comprises a first semimetal layer and a second semimetal layer over the first semimetal layer, and each of the second source/drain contacts comprises a third semimetal layer and a fourth semimetal layer over the third semimetal layer, wherein a thickness ratio of the first semimetal layer to the second semimetal layer in the NFET is greater than a thickness ratio of the third semimetal layer to the fourth semimetal layer in the PFET.

2. The device of claim 1, wherein the first semimetal layer and the third semimetal layer comprise a same material.

3. The device of claim 1, wherein the first semimetal layer is an antimony layer.

4. The device of claim 1, wherein the third semimetal layer is an antimony layer.

5. The device of claim 1, wherein the second semimetal layer and the fourth semimetal layer comprise a same material.

6. The device of claim 1, wherein the second semimetal layer is a platinum layer.

7. The device of claim 1, wherein the fourth semimetal layer is a platinum layer.

8. The device of claim 1, wherein the thickness ratio of the first semimetal layer to the second semimetal layer in the NFET is greater than 100%.

9. The device of claim 1, wherein the thickness ratio of the third semimetal layer to the fourth semimetal layer in the PFET is less than 100%.

10. The device of claim 1, further comprising:
a first capping layer capping the first source/drain contacts of the NFET; and
a second capping layer capping the second source/drain contacts of the PFET, wherein the first capping layer and the second capping layer are formed of different materials.

11. The device of claim 10, wherein the first capping layer is formed of silicon oxynitride, hafnium oxide, aluminum oxide, or titanium oxide.

12. The device of claim 10, wherein the second capping layer is formed of molybdenum oxide, nitrogen dioxide, tungsten oxide, or iodine.

13. A device comprising:
a first 2D semiconductor layer over a substrate;
a first source/drain contact interfacing a first region of the first 2D semiconductor layer; and
a second source/drain contact interfacing a second region of the first 2D semiconductor layer spaced apart from the first region of the first 2D semiconductor layer,
wherein the first source/drain contact comprises a first antimony layer interfacing the first region of the first 2D semiconductor layer, and a first platinum layer over the first antimony layer.

14. The device of claim 13, wherein the first antimony layer has a thickness less than a thickness the first platinum layer.

15. The device of claim 13, wherein the first antimony layer has a thickness greater than twice a thickness of the first platinum layer.

16. The device of claim 13, further comprising:
a second 2D semiconductor layer over the substrate;
a third source/drain contact interfacing a first region of the second 2D semiconductor layer; and
a fourth source/drain contact interfacing a second region of the second 2D semiconductor layer,
wherein the third source/drain contact comprises a second antimony layer and a second platinum layer over the second antimony layer, wherein the first antimony layer and the second antimony layer have different thicknesses, and the first platinum layer and the second platinum layer have a same thickness.

17. A method comprising:
forming a dielectric layer over a substrate;
forming a first 2D semiconductor layer and a second 2D semiconductor layer over the dielectric layer;
forming a first antimony layer and a second antimony layer in contact with opposite sides of the first 2D semiconductor layer;
forming a third antimony layer and a fourth antimony layer in contact with opposite sides of the second 2D semiconductor layer, wherein the third antimony layer has a thickness greater than a thickness of the first antimony layer; and
forming a first platinum layer, a second platinum layer, a third platinum layer, and a fourth platinum layer over the first antimony layer, the second antimony layer, the third antimony layer, and the fourth antimony layer, respectively.

18. The method of claim 17, wherein forming the first 2D semiconductor layer and the second 2D semiconductor layer comprises:
forming a first transition metal layer and a second transition metal layer over the dielectric layer; and
selenizing the first transition metal layer and the second transition metal layer into the first 2D semiconductor layer and the second 2D semiconductor layer.

19. The method of claim 17, further comprising:
forming a back gate structure over the substrate, wherein the dielectric layer is formed over the back gate structure.

20. The method of claim 17, wherein the fourth antimony layer has a thickness greater than a thickness of the second antimony layer.
